(19) United States
(12) Patent Application Publication
(10) Pub. No.: US 2018/0249580 A1
(43) Pub. Date: Aug. 30, 2018

(54) OPTICAL PROCESSING DEVICE AND OPTICAL PROCESSING METHOD

(71) Applicant: USHIO DENKI KABUSHIKI KAISHA, Tokyo (JP)

(72) Inventors: Shun MARUYAMA, Tokyo (JP); Hiroki HORIBE, Tokyo (JP); Tomoyuki HABU, Tokyo (JP); Shinichi ENDO, Tokyo (JP); Akira AIBA, Tokyo (JP); Masaki MIURA, Tokyo (JP)

(73) Assignee: USHIO DENKI KABUSHIKI KAISHA, Tokyo (JP)

(21) Appl. No.: 15/547,937

(22) PCT Filed: Jan. 18, 2016
(86) PCT No.: PCT/JP2016/000226

§ 371 Date: Aug. 1, 2017

(30) Foreign Application Priority Data
Feb. 6, 2015 (JP) 2015-022099
Feb. 18, 2015 (JP) 2015-029895
May 22, 2015 (JP) 2015-104673

(51) Int. Cl. H05K 3/00; H01L 21/304; H01L 21/67

(52) U.S. Cl. CPC H05K 3/0055; H05K 3/0088; H05K 3/0035; H01L 21/67115; H01L 21/304

(57) ABSTRACT

Disclosed herein is an optical processing device and an optical processing method. The optical processing device comprises: a light source unit configured to emit light; and a processing unit configured to expose an object to be processed to the light emitted from the light source unit. The processing unit includes: a processing region in which the object to be processed is held and exposed to the light in an atmosphere of a processing gas; and a preparatory region through which the processing gas passes, while being exposed to the light, to move toward the processing region, the preparatory region being configured to prevent the object to be processed from being arranged thereon.

### TECHNICAL FIELD

The present invention relates to an optical processing device and an optical processing method. More particularly, the present invention relates to an optical processing device and an optical processing method that are applicable and preferable for an optical ashing treatment of a resist during a fabrication process of a semiconductor or a liquid crystal or the like, a removal treatment of a resist adhered to a patterned surface of a template in a nanoimprint device, a dry cleaning treatment of a glass substrate or a silicon wafer or the like for a liquid crystal, and a removal treatment of a smear (i.e., desmear) during a fabrication process of a printed circuit board and the like.

### BACKGROUND ART

Conventionally, an optical processing device and an optical processing method using ultra violet light have been known as the optical processing device and the optical processing method usable for, for example, an optical ashing treatment of a resist during a fabrication process of a semiconductor or a liquid crystal or the like, a removal treatment of a resist adhered to a patterned surface of a template in a nanoimprint device, a dry cleaning treatment of a glass substrate or a silicon wafer or the like for a liquid crystal, and a removal treatment of a smear (i.e., desmear) during a fabrication process of a printed circuit board and the like.

In particular, preferably being employed is a certain device or a method in which an active species (activated species), such as ozone or an oxygen radical or the like, is used, which is generated with vacuum ultra violet light emitted from an excimer lamp or the like, because it is capable of performing a desired predetermined process more efficiently in a short period of time.

For example, PATENT LITERATURE 1 (International Publication of PCT International Application WO2014/104154 A) has proposed a method of irradiating a substrate with the ultra violet light as a desmear treatment method (method of performing desmear) of a via hole. In particular, the PATENT LITERATURE 1 has proposed to irradiate the substrate in which the via hole is formed with the ultra violet light in an atmosphere containing oxygen.

### LISTING OF REFERENCES

### Patent Literature

PATENT LITERATURE 1: International Publication of PCT International Application WO2014/104154 A

### SUMMARY OF THE INVENTION

### Problems to be Solved by the Invention

The inventors of the present invention have found out the facts that, as a result of an earnest study or investigation, a higher processing efficiency can be achieved by (1) irradiating the substrate with the ultra violet light through a gas such as oxygen or ozone, or a gas containing oxygen or the ozone or the like; and by (2) moving a processing gas (or treatment gas) so as to flow on the substrate instead of sealing the processing gas within a processing chamber.

In connection with the above findings, however, the inventors of the present invention have also found out, as a result of an experiment, the fact that a speed for removing the smear (a processing speed of the desmear) is slower in a peripheral region of the substrate that is closer to an gas inlet port than in an inner region at a downstream side with respect to a flow of the processing gas, in other words, the fact that a non-uniformity (irregularity or unevenness) occurs in (within) the substrate in the removal process of the smear.

Taking the above mentioned circumstances into consideration, the present invention has been made in order to solve the above mentioned problems and an object thereof is to suppress the non-uniformity from occurring on the substrate.

### Solution to Problems

In order to solve the above mentioned problems, according to one aspect of an optical processing device of the present invention, there is provided an optical processing device comprising: a light source unit configured to emit light; and a processing unit configured to expose an object to be processed (to-be-processed object) to be processed to the light emitted from the light source unit.

The processing unit includes: a processing region in which the object to be processed is held and exposed to the light in an atmosphere of a processing gas; and a preparatory region through which the processing gas passes, while being exposed to the light, to move toward the processing region, the preparatory region being configured to prevent the object to be processed from being arranged thereon.

Hereinafter throughout the specification, a “processing gas (also referred to as “treatment gas)” means a gas that processes (or treats) an object to be processed, and also a gas that acquires a processing capability with being exposed to light emitted from a light source unit. One of preferable combination of the light and the processing gas may include, for example, a combination of vacuum ultra violet light and oxygen. When oxygen is exposed to the vacuum ultra violet light, an oxygen radical (that is, active species) or ozone is produced (generated) so as to oxidize a surface of the object to be processed or an accretion (adhesive material) thereof.

According to the optical processing device of the present embodiment, the processing gas, which has acquired the processing capability by passing through the preparatory region, reaches to the processing region and then processes (treats) the object to be processed. Thus, it makes it possible to suppress the difference in the processing speed or the like between a peripheral region close to a gas inlet port and an inner region at a downstream side in the substrate, and also suppress the processing non-uniformity. With the preparatory region being provided to be sufficiently long, it makes it possible to prevent the processing non-uniformity from occurring in a substrate.

Furthermore, according to another aspect of the present invention, in the above mentioned optical processing device, preferably, the processing unit may include a placing base configured to place the object to be processed; and a forming instrument (widget) configured to prevent the object to be processed from being placed on a part of the placing base to form the preparatory region.

According to the above mentioned optical processing device, it makes it possible to form the preparatory region by the forming instrument in an assured manner.

Yet furthermore, according to yet another aspect of the present invention, in the above mentioned optical processing device, preferably, the light source unit may be provided with a window plate configured to transmit light, the processing unit may be provided with a placing base opposing to the window plate and configured to place the object to be processed thereon, and the preparatory region may be a region lying between the window plate and a part of the placing base on which the object to be processed is not placed.

According to the above mentioned optical processing device, it makes it possible to stabilize a flow of the processing gas in the preparatory region. As a result, it also make it possible to stabilize the processing capability acquired by the processing gas.

Yet furthermore, according to yet another aspect of the present invention, in the above mentioned optical processing device, preferably, in the preparatory region, a bottom face thereof opposing to the light source unit may be distant from the light source unit as compared to a surface of the object to be processed opposing to the light source unit.

According to the above mentioned optical processing device, as the bottom face of the preparatory region is more distant (farther) from the light source device as compared to the surface of the object to be processed, it makes it possible to suppress the breadth or area of the preparatory region so as to contribute the downsizing of the entire optical processing device.

Yet furthermore, according to yet another aspect of the present invention, in the above mentioned optical processing device, preferably, the preparatory region may have a flow channel cross sectional area that is larger than that of the processing region.

With the preparatory region being so configured, it makes it possible to shorten the length of the preparatory region in the direction along the flow of the processing gas.

Yet furthermore, according to yet another aspect of the present invention, in the above mentioned optical processing method, preferably, in the processing step, the object to be processed may be irradiated with the light emitted from the light source in an atmosphere of the processing gas having a faster flow rate than in the preparatory region in the processing region continuous from the preparatory region, the processing region having a flow channel cross sectional area smaller than that of the preparatory region.

According to the above mentioned optical processing method, it makes it possible to suppress the processing non-uniformity in the substrate and also to suppress the breadth or area of the preparatory region.

Yet furthermore, according to yet another aspect of the present invention, in the above mentioned optical processing device, preferably, the light emitted from the light source unit may be ultra violet light, in the processing region, the object to be processed may be held while being heated and exposed to the ultra violet light in the atmosphere of the processing gas, and the optical processing device may further comprise a temperature control unit configured to control heating temperature at least in the processing region to allow the temperature of the preparatory region to be lower than temperature of the processing region.

Hereinafter throughout the specification, a “processing gas (also referred to as “treatment gas”)” means a gas that processes (treats) an object to be processed, and also a gas that acquires a processing capability with being exposed to the ultra violet light. One of preferable combination of the light and the processing gas may include, for example, a combination of vacuum ultra violet light and oxygen. When oxygen is exposed to the vacuum ultra violet light, an oxygen radical (that is, active species) or ozone is produced (generated) so as to oxidize a surface of the object to be processed or an accretion (adhesive material) thereof. When combining with oxygen, the oxygen radical (active species) or the ozone is produced by using the vacuum ultra violet light having a wavelength equal to or less than 220 nm.

As described above, when the ozone is produced in the preparatory region, the preparatory region serves as an ozone producing region that produces ozone prior to the optical processing.

According to the optical processing device of the present embodiment, the processing gas, which has acquired the processing capability by passing through the preparatory region, reaches to processing region and then processes the object to be processed. Thus, it makes it possible to suppress the difference in the processing speed of the like between the peripheral region of the substrate close to the gas inlet port and the inner side region of the substrate at the downstream side, and also to suppress the processing non-uniformity.

In addition, the processing capability of the processing gas can increase in a short period of time because the temperature of the preparatory region becomes lower than that of the processing region. As a result, it makes it possible to prevent the preparatory region from being enlarged so as to contribute the downsizing of the device.

Yet furthermore, according to yet another aspect of the present invention, in the above mentioned optical processing device, preferably, the processing unit may further comprise: a stage having the processing region and the preparatory region and being formed integrally; and a plurality of heating mechanisms provided at the processing region and the preparatory region, respectively, and respective heating temperatures are controlled by the temperature control unit independently from each other between the processing region and the preparatory region.

According to the above mentioned optical processing device, it makes it possible to control the respective temperatures of the processing region and the preparatory region to be appropriate temperatures for the processing in respective regions, respectively.

Yet furthermore, alternatively, according to yet another aspect of the present invention, in the above mentioned optical processing device, preferably, the processing unit may further comprise: a stage having the processing region and the preparatory region and being formed integrally; and a heating mechanism provided solely at the processing region and heating temperature of the heating mechanism is controlled by the temperature control unit.

According to the above mentioned optical processing unit, it makes it possible to the preparatory region to be lower in temperature than the processing region in an assured manner.

Yet furthermore, according to yet another aspect of the present invention, in the above mentioned optical processing device, preferably, the processing unit may further comprise: a first stage having the processing region; a second stage having the preparatory region and separated from the first stage; and a plurality of heating mechanisms provided at the processing region and the preparatory region, respectively, and respective heating temperatures are controlled by the temperature control unit independently from each other between the processing region and the preparatory region.

According to the above mentioned optical processing unit, it makes it possible to eliminate a higher processing accuracy for the preparatory region as compared to the processing region configured to hold the object to be processed. As a result, it makes it possible to simplify the second stage so as to suppress the complexity or labor and the cost associated with fabricating the second stage, by separating the second stage from the first stage.

Yet furthermore, according to yet another aspect of the present invention, in the above mentioned optical processing device, preferably, the processing unit may further comprise: a first stage having the processing region; a second stage having a preparatory region and being separated from the first stage; and a heating mechanism provided solely at the processing region, and heating temperature of the heating mechanism is controlled by the temperature control unit.

According to the above mentioned optical processing unit, it makes it possible to allow the preparatory region to be lower in temperature than the processing region in an assured manner. In this regard, in particular, it is effective to arrange the first stage to be contactless with the second stage.

Still yet furthermore, in order to solve the above mentioned problem, according to one aspect of an optical processing method of the present invention, there is provided a method comprises: a preparatory step of irradiating a processing gas passing through a preparatory region with light emitted from a light source; and a processing step of irradiating an object to be processed arranged in an atmosphere of the processing gas with the light emitted from the light source in a processing region continuous from the preparatory region.

According to the above mentioned optical processing method, after the processing gas has acquired the processing capability in the preparatory step, the object to be processed undergoes treatment (is processed) in the processing step. As a result, it makes it possible to suppress the processing non-uniformity in the substrate.

Yet furthermore, in the above mentioned optical processing method, the processing step may irradiate the object to be processed arranged in the atmosphere of the processing gas with the light emitted from the light source in the processing region continuous from the preparatory region, the processing region having a smaller flow channel cross sectional area than that of the preparatory region, and the processing gas having a faster flow rate in the processing region than in the preparatory region.

According to the above mentioned optical processing method, it makes it possible to suppress the processing non-uniformity on the substrate and also to prevent the preparatory region from being enlarged.

Still yet furthermore, in the above mentioned optical processing method, the preparatory step may irradiate the processing gas passing through the preparatory region with ultra violet light emitted from the light source; and the processing step may irradiate the object to be processed arranged and heated in an atmosphere of the processing gas in the processing region, heating temperature in the processing step may be controlled and temperature of the preparatory region in the preparatory step may be made to be lower than the heating temperature.

According to the optical processing method of the present embodiments, the processing gas acquires the processing capability by passing through the preparatory region, and then reaches to the processing region to process (treat) the object to be processed. Thus, it makes it possible to suppress the difference in the processing speed between the peripheral region of the substrate close to the gas inlet port and the inner region of the substrate at the downstream side, and also to prevent the processing non-uniformity from occurring.

In addition, as the temperature in the preparatory region is kept lower than in the processing region, it makes it possible to increase the processing capability of the processing gas in a short period of time. Thus, it makes it possible to prevent the preparatory region from being enlarged so as to contribute the downsizing or the like of the optical processing device.

### Advantageous Effect of the Invention

According to an optical processing device and an optical processing method of the present invention, it makes it possible to prevent a processing non-uniformity in a substrate from occurring.

The above mentioned and other not explicitly mentioned objects, aspects and advantages of the present invention will become apparent to a skilled person from the following detailed description when read and understood in conjunction with the appended claims and drawings.

### BRIEF DESCRIPTION OF DRAWINGS

FIG. 1 is a schematic view showing an exemplary configuration of an optical processing device according to a first embodiment.

FIG. 2 is a cross sectional view showing a schematic cross sectional structure of a substrate.

FIG. 3 is a view showing a first phase of an action in a desmear treatment.

FIG. 4 is a view showing a second phase of the action in the desmear treatment.

FIG. 5 is a view showing a third phase of the action in the desmear treatment.

FIG. 6 is a view showing a final phase of the action in the desmear treatment.

FIG. 7 is a view showing an action in a preparatory region.

FIG. 8 is a graph showing a relationship between an irradiation of ultra violet light and a concentration of an active species.

FIG. 9 is a schematic view showing an exemplary configuration of an optical processing device according to a second embodiment.

FIG. 10 is a schematic view showing an exemplary configuration of an optical processing device according to a third embodiment.

FIG. 11 is a view showing an action in the preparatory region according to the third embodiment.

FIG. 12 is a schematic view showing an exemplary configuration of an optical processing device according to a fourth embodiment.

FIG. 13 is a schematic view showing an exemplary configuration of an optical processing device according to a fifth embodiment.

FIG. 14 is a view showing an action in the preparatory region according to the fifth embodiment.

FIG. 15 is a graph showing a relationship between an irradiation of ultra violet light and a concentration of an active species.

FIG. 16 is a schematic view showing an exemplary configuration of an optical processing device according to a sixth embodiment.

FIG. 17 is a schematic view showing an exemplary configuration of an optical processing device according to a seventh embodiment.

FIG. 18 is a schematic view showing an exemplary configuration of an optical processing device according to a eighth embodiment.

### DESCRIPTION OF EMBODIMENTS

### First Embodiment

Hereinafter, embodiments of the present invention will be described with reference to the accompanying drawings in detail.

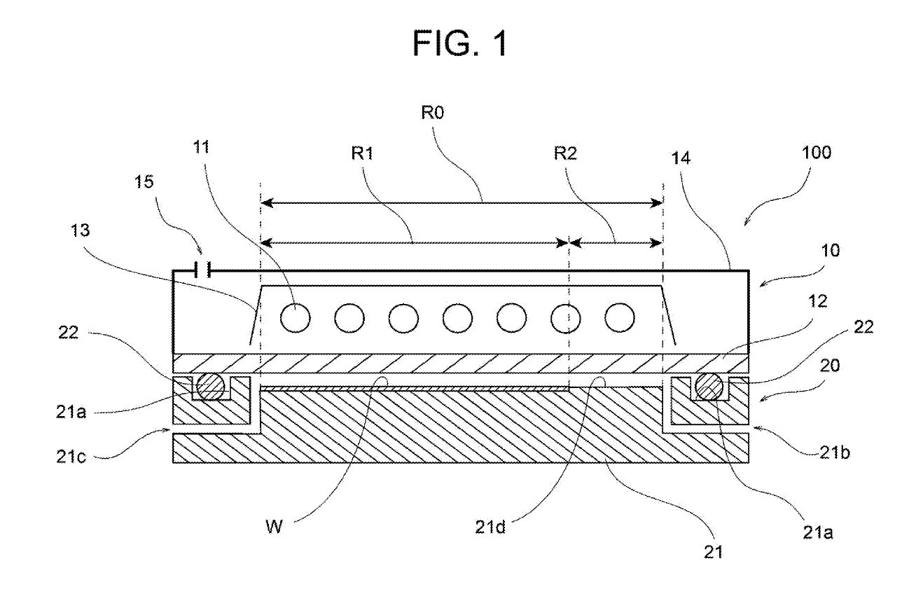

FIG. 1 is a schematic view showing an exemplary configuration of an optical processing device according to the present embodiment. The present embodiment will exemplarily describe an application example in which the optical processing device is applied to a desmear treatment device.

### (Configuration of the Optical Processing Device)

An optical processing device 100 is provided with a processing unit 20 that holds and processes a substrate W inside thereof, and a light irradiation unit 10 that accommodates a plurality of ultra violet light sources 11 emitting, for example, ultra violet light and irradiates the substrate W of the processing unit 20 with light emitted from the ultra violet light sources 11. The light irradiation unit 10 corresponds to an example of a light source unit according to the present invention, and the processing unit 20 corresponds to an example of a processing unit according to the present invention.

The light irradiation unit 10 is provided with a casing 14 in a boxed shape. On a face positioned at a lower side of the casing 14, a window member 12 made of, for example, quartz glass or the like, which transmits, for example, vacuum ultra violet light, is provided airtightly. Inside the light irradiation unit 10, an inert gas, such as nitrogen gas or the like, is supplied from the supply port 15 and kept in an inert gas atmosphere. At the upper side of the ultra violet light sources 11 inside the light irradiation unit 10, a reflector (reflective) mirror 13 is provided to reflect light emitted from the ultra violet light sources 11 toward the window member 12 side. The window member 12 corresponds to an exemplary window plate according to the present invention. Light from the ultra violet light sources 11 is irradiated onto an entire effective irradiation region R0, which corresponds to a full (maximum) width of the reflective mirror 13, almost in a uniformed manner.

The ultra violet light sources 11 emit, for example, vacuum ultra violet light (ultra violet light having a wavelength equal to or less than 200 nm), respectively, and various known lamps can be used as the ultra violet light sources. For example, a xenon excimer lamp enclosing a xenon gas (wavelength of 172 nm) and a low pressure mercury lamp (wavelength of 185 nm) may be used. Amongst those lamps, for example, the xenon excimer lamp can be preferably used as the light source for the desmear treatment.

The processing unit 20 is provided with a stage 21 which suctions to hold the substrate W, which undergoes (subject to) the ultra violet light irradiation treatment (e.g., desmear treatment), on the surface thereof, with the stage 21 opposing to the window member 12. The stage 21 corresponds to an exemplary placing base according to the present invention. At an outer circumference of the stage, an outer circumference groove 21a is provided. An O-ring 22 is sandwiched between the outer circumference groove 21a and the window member 12 of the light irradiation unit 10 so that the light irradiation unit 10 and the processing unit 20 are assembled airtightly. A thermal resistance heater, which is not shown in the drawings, is incorporated into the stage 21, and heats the stage 21 with the substrate W entirely (in whole) during the desmear treatment.

At one side edge portion of the stage 21 (the right side in FIG. 1), a gas inlet port 21b for supplying the processing gas (treatment gas) is provided, and at the other side edge portion of the stage 21 (the left side in FIG. 1), a gas outlet port 21c is provided. Although, in FIG. 1, one gas inlet port 21b and one gas outlet port 21c only are illustrated, a plurality of gas inlet ports 21b and a plurality of gas outlet ports 21c are arranged at the stage 21, respectively. A plurality of gas inlet ports 21b are aligned in the direction perpendicular to the paper surface of FIG. 1. Likewise, a plurality of gas outlet ports 21c are aligned in the direction perpendicular to the paper surface of FIG. 1. Respective gas inlet ports 21b are connected to a treatment gas supply unit (not shown) and are supplied with the processing gas, respectively. Also, respective gas outlet ports 21c are connected to a gas exhaust unit (not shown), respectively.

Here, the processing gas may be considered to include, for example, an oxygen gas, a mixed gas of oxygen and ozone or watery vapor, and a gas in which an inert gas or the like is mixed with those gases. According to the present embodiment, the oxygen gas is assumed to be used. During the substrate W is being irradiated with the ultra violet light from the light irradiation unit 10, the processing gas is supplied from the gas inlet port 21b and then discharged from the gas outlet port 21c. The processing gas moving from the gas inlet port 21b toward the gas outlet port 21c is assumed to flow between the window member 21 and the substrate W from the right side to the left side in FIG. 1.

The stage 21 is provided with a convex portion 21d in an upstream side region R2 (right side in FIG. 1) with respect to the flow of the processing gas. The substrate W is prevented from being placed on the region R2 on the stage 21 by the convex portion 21d. In other words, a stepped portion (level difference) is formed on the stage 21 by the region R1, which places and holds the substrate W, and the region R2, which prevents the substrate W from being placed. The convex portion 21d corresponds to an exemplary forming instrument (widget) according to the present invention.

Hereinafter throughout the specification, amongst regions on the stage 21, in some cases, the region R1, which places and processes the substrate W, may be referred to as a processing (treatment) region R1, and the region R2, which is provided with the convex portion 21d to prevent the substrate W from being placed, may be referred to as a preparatory region R2.

According to the present embodiment, a protrusion amount of the convex portion 21d (in other words, the height of the stepped portion of the stage 21) is equivalent to the thickness of the substrate W. For this reason, gaps (clearances) through which the processing gas flows are become equivalent between the processing region R1 and the preparatory region R2 so that the flow of the processing gas from the gas inlet port 21b toward the gas outlet port 21c are stabilized. Furthermore, the vacuum ultra violet light radiated from the light irradiation unit 10 reaches to both the processing region R1 and the preparatory region R2 with an equivalent intensity.

### (Structure of Substrate)

Although various structure may be used for the substrate W, as a substrate W which undergoes the treatment (processing) by the light processing unit 10, hereinafter a simplified exemplary structure will be described below.

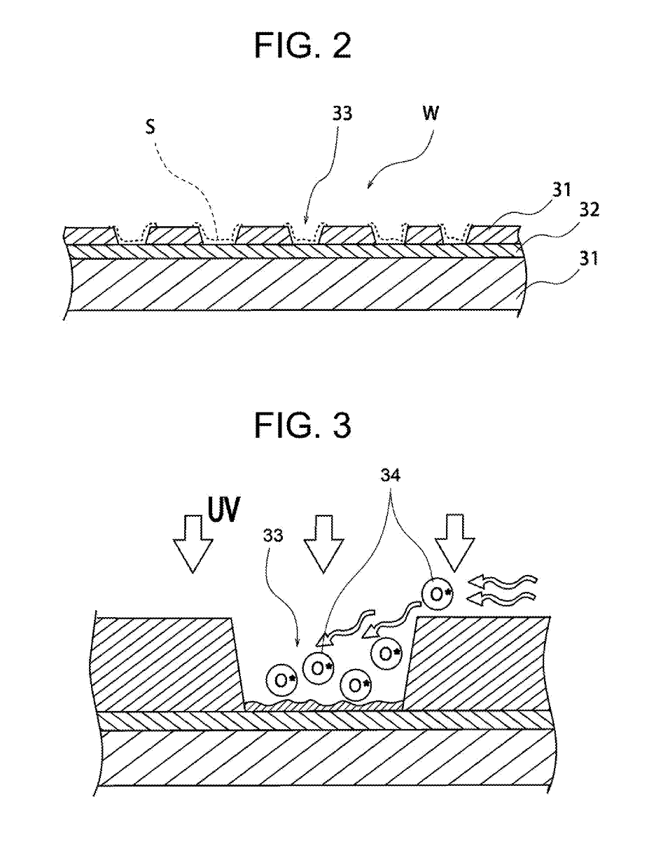

FIG. 2 is a cross sectional view showing an exemplary schematic structure of the substrate W.

The substrate W is, for example, an intermediate wiring substrate material which is obtained during the manufacturing of a multilayer wiring substrate onto which a semiconductor element, such as a semiconductor integrated circuit element or the like, is mounted.

In the multilayer wiring substrate, in order to electrically connect one wiring layer to another wiring layer, a via hole is formed that penetrates one or plural insulating layers in the thickness direction to extend therethrough. During the manufacturing process of the multilayer wiring substrate, the via hole 33 can be formed by applying, for example, the layer processing to the wiring substrate material formed by layering an insulating layer 31 and a wiring layer 32 and removing a part of the insulating layer 31.

However, on a surface of a bottom portion or a side portion of the formed via hole 33, a smear (residue) S adheres thereto due to a material constituting the insulating layer 31. When the plating treatment (plate processing) is applied in the via hole 33 with the smear S adhering thereto, in some cases, it entails a connection failure or a poor connection between the wiring layers. In order to avoid such connection failure, the desmear treatment that removes the smear S adhering to the via hole 33 is applied onto the wiring substrate material (substrate W) in which the via hole 33 is formed.

When the substrate W is placed on the stage 21 shown in FIG. 1, the substrate W is placed such that an opening of the via hole 33 faces to the light irradiation unit 10, in other words, the smear S is exposed to the ultra violet light emitted from the ultra violet light source 11.

### (Procedure of Desmear Treatment)

Next, referring back to FIG. 1, a procedure of the desmear treatment performed by the light processing device 100 will be described in detail.

First, the substrate W to be processed is conveyed from outside the processing unit 20 into the processing unit 20, and then placed on the stage 21. The substrate W is held on the stage 21 by the vacuum suction or the like. Subsequently, the processing gas is supplied from the gas inlet port 21b into the processing unit 20 by the treatment gas supply unit.

Simultaneously with the supply of the processing gas, the ultra violet light sources 11 are lighted up, and the ultra violet light is radiated from the irradiation unit 10 toward the processing unit 20 to irradiate the substrate W with the ultra violet light through the processing gas.

The processing gas that has been irradiated with the ultra violet light produces the active species such as ozone or an oxygen radical or the like, and reacts with the smear in the via hole so as to remove the smear, which will be described in detail later. A gas of, for example, carbon dioxide, which is produced with the processing gas reacting with the smear, taps into a flow of a newly supplied processing gas, is conveyed toward the downstream side, sucked from the gas outlet port 21c, and then discharged by the exhaust unit.

The substrate W, after being treated (processed), is removed from the stage 21 and carried out to the outside of the processing unit 20.

### (Action of Desmear Treatment)

Hereinafter, an action of the desmear treatment will be described in detail.

FIGS. 3 to 6 are views showing respective phases of the action of the desmear treatment, respectively.

In a first phase shown in FIG. 3, the processing gas supplied from the gas inlet port is irradiated with the ultra violet light, as shown in the arrow directed downwardly from an upper side in FIG. 3, so as to produce the ozone or the oxygen radical, which serves as the active species 34, from oxygen contained in the processing gas (here, only the oxygen radical is exemplarily illustrated in FIG. 3). The produced active species 34 advances into the via hole 33 of the substrate W.

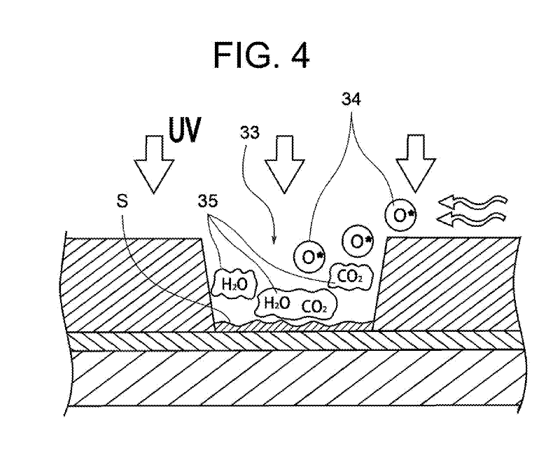

In a second phase shown in FIG. 4, the active species 34 reacts with the smear S in the via hole 33, and a part of the smear S is decomposed as well as a part of the smear S being decomposed with the smear S being irradiated with the ultra violet light. In addition, with the smear S being so decomposed, a reaction product gas 35 such as a carbon dioxide gas or watery vapor or the like is produced.

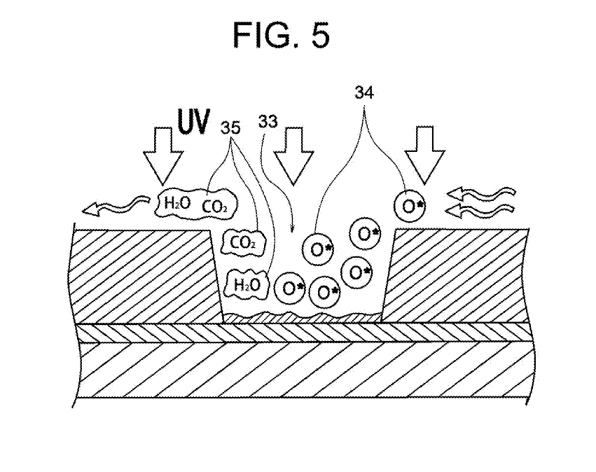

Subsequently, in a third phase shown in FIG. 5, the reaction product gas 35 is swept away (drifts) from the via hole 33 toward the gas outlet port side (left side in FIG. 5) by the newly supplied processing gas containing the active species 34, which is flowing from the gas inlet port side (right side in FIG. 5). As the reaction product gas 35 is being discharged, the newly supplied processing gas containing the active species 34 advances into the via hole 33.

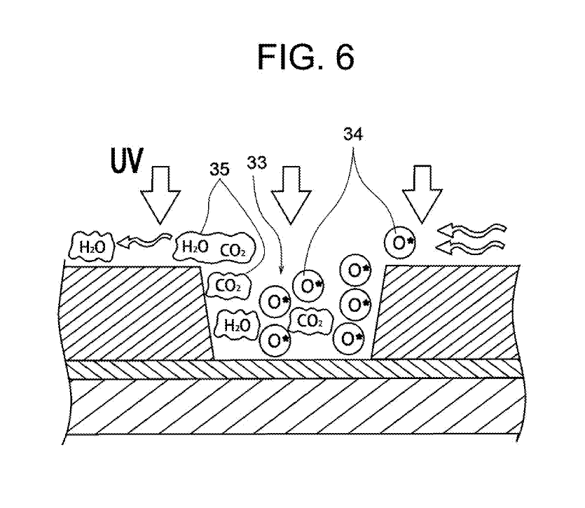

As a result of repeating the radiation of the ultra violet light, the advancement of the active species 34, and the discharge (exhaust) of the reaction product gas 35, in a final phase shown in FIG. 6, the smear S is almost completely removed in the via hole 33. The reaction product gas 35 swept away outside the via hole 33 taps into the flow of the processing gas on the substrate W and is discharged from the gas outlet port 21c shown in FIG. 1.

The processes of the optical processing shown in FIGS. 3 to 6 correspond to exemplary processes of the processing according to the present invention.

As described above, in the desmear treatment, it is of great importance in order to improve the processing efficiency that the active species, such as the oxygen radical or the ozone or the like, is produced by radiating the ultra violet light and advances into the via hole 33, as well as the ultra violet light itself is also irradiated onto the inside of the via hole 33.

For this reason, it is preferable to set the distance between the window member 12 and the substrate W shown in FIG. 1 to be, for example, equal to or less than 1 mm, and more preferably, in particular, equal to or less than 0.5 mm. With the distance so being set, it makes it possible to produce the oxygen radial or the ozone in a stable manner and also to allow the vacuum ultra violet light reaching to the surface of the substrate W to have the sufficient intensity (that is, amount of light).

### (Action in Preparatory Region)

In the meantime, in the conventional light processing device, it is assumed to be of importance to efficiently use the ultra violet light radiated from the light irradiation unit 10. For this reason, in general, a region irradiated with the ultra violet light having the radiation (radiative) intensity effective for the desired processing is required to cover the entire substrate W. Nevertheless, the conventional optical processing device is not set to irradiate a region broader than the entire substrate W.

For this reason, in the conventional optical processing device, it is considered that, in a peripheral region close to the gas inlet port, before the active species having a sufficient concentration is produced by the ultra violet light, the active species is swept away toward the downstream side by the newly supplied processing gas. For this reason, in the peripheral region, it is assumed that the active species reaching to the via hole has the lower concentration, the processing speed of the desmear treatment becomes lower than in an inner region positioned at the downstream side of the processing gas. As a result, it is assumed that the processing (treatment) non-uniformity occurs in the substrate.

In contrast, according to the optical processing device 100 shown in FIG. 1, the stage 21 is provided with the convex portion 21d to prevent the substrate W from being placed so as to form the preparatory region R2. The preparatory region R2 is also irradiated with the light similarly to the processing region R1.

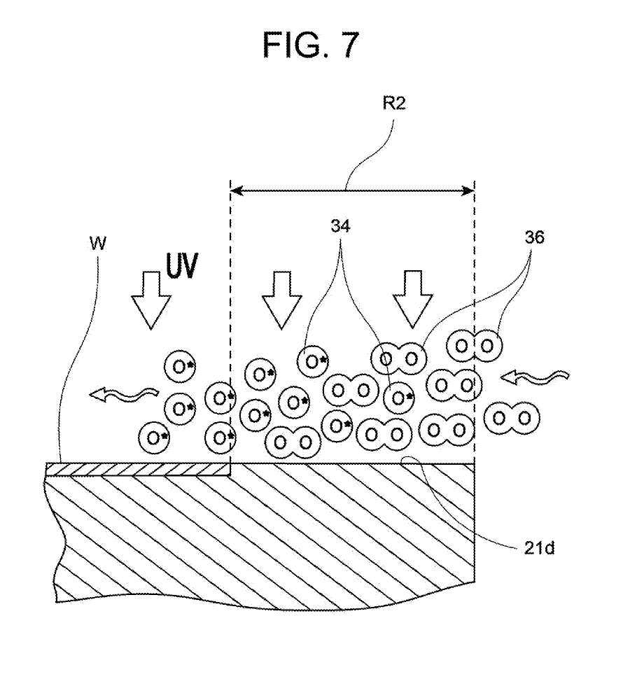

FIG. 7 is a view showing an action in the preparatory region R2.

In the preparatory region R2 formed by the convex portion 21d of the stage 21, the processing gas 36, such as an oxygen gas, is irradiated with the ultra violet light from the light irradiation unit so as to produce the active species 34 such as the ozone or the oxygen radical.

Because the preparatory region R2 does not place the substrate W (in other words, does not has the smear), while the produced active species 34 is pushed by the newly supplied processing gas 36 and swept away toward the downstream side, the concentration of the active species 34 is gradually increased so as to be stabilized. In other words, the preparatory region R2 is a region that functions to stabilize the concentration of the active species 34 with the processing gas 36 being irradiated with the ultra violet light.

According to the present embodiment, as the processing gas flows through the gap (clearance), which is temporally and spatially stabilized, lying between the stage and the window member, the flow of the processing gas also becomes stable. As a result, the concentration of the active species 34 is stabilized in an assured manner.

The processing gas, in which the concentration of the active species 34 is increased and stabilized in the preparatory region R2, reaches onto the substrate W and advances into the via hole, while the activity thereof being kept, so as to react with the smear and remove the smear. When the treatment gas reaches onto the substrate W, the concentration of the active species 34 of the treatment gas is sufficiently high and stabilized. For this reason, the processing speed in the respective positions of the substrate W is sufficiently high at any positions from the upstream side to the downstream side in the flow of the processing gas so as to prevent the treatment non-uniformity from occurring in the substrate W.

The process in the preparatory region shown in FIG. 7 corresponds to an exemplary preparatory step according to the present invention.

It should be noted that, as one example, FIG. 7 schematically illustrates a state in which oxygen is irradiated with the ultra violet light and the oxygen radical serving as the active species is produced. Nevertheless, as the active species, the ozone is also produced. Also, when the processing gas contains the ozone, the oxygen radical is also produced from the ozone by the ultra violet light irradiation. Yet also, when the processing gas contains the watery vapor or hydrogen peroxide, the hydroxyl radical serving as the active species is produced by the ultra violet light irradiation.

The action described in referring to FIG. 7 in the preparatory region R2 similarly occurs for both of those various kinds of treatment gases and the active species so as to prevent the processing (treatment) non-uniformity from occurring in the substrate W.

Next, the appropriate and preferable size of the preparatory region (in other words, the length thereof in the direction along the flow of the processing gas) will be considered and addressed.

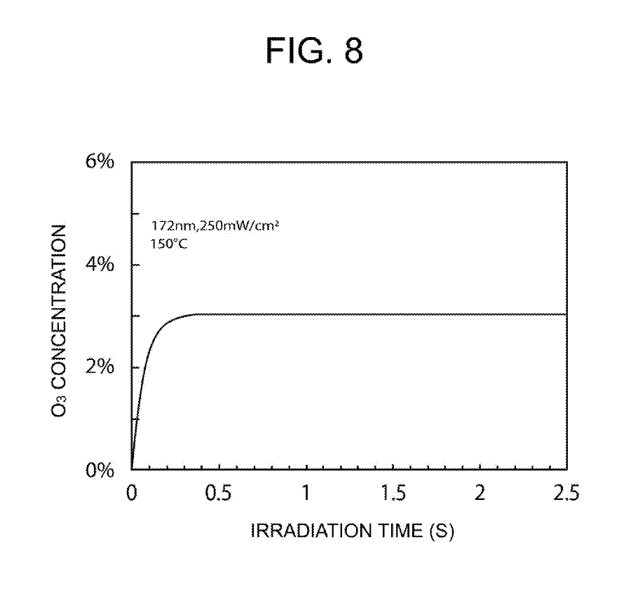

FIG. 8 shows a graph representing the relationship between the ultra violet light irradiation and the concentration of the active species.

In the graph in FIG. 8, the horizontal axis denotes the irradiation time of the ultra violet light and the vertical axis denotes the concentration of ozone serving as the active species. Also, in an example shown in FIG. 8, oxygen is used as the processing gas, the vacuum ultra violet light having the wavelength of 172 nm is used as the ultra violet light with the intensity of 250 mW/cm², and the stage is heated to 150 degrees Celsius.

The concentration of the active species (ozone) increases as the irradiation time increases from zero seconds. As the concentration the active species increases, the extinction (annihilation) amount of the active species also increases due to the reaction between active species or the like. As a result, the concentration becomes stabilized at, for example, the concentration of approximately 3%. In the graph in FIG. 8, the concentration of the active species becomes stable at the irradiation time of approximately 0.5 seconds.

In this regards, as a result of the earnest study and investigation by the inventors of the present invention, it has been turned out that this kind of stabilization of the concentration of the active species can be achieved with the ultra violet light irradiation for approximately 0.5 seconds and at most approximately 1.0 second, although more or less varying depending on, for example, the intensity of the ultra violet light or the temperature of the processing gas or the like.

In addition, it has been turned out that the concentration is similarly stabilized in the case of the oxygen radical as well.

Accordingly, it is preferable to set the length of the preparatory region to be the length that requires the passage (transit) time of the processing gas equal to or greater than 0.5 seconds and equal to or less than 1.0 second depending on the flow rate of the processing gas. In order to avoid the obstruction by the reaction product (that is, lowering of the reaction speed), it is preferable to keep the flow rate of the treatment gas to be high to some extent, and for example, the flow rate of 50 to 500 mm/s is employed. Thus, it is assumed that the length of the preparatory region has preferably approximately 25 to 500 mm.

### Second Embodiment

Hereinafter, referring to the drawings, a second embodiment of the present invention will be described in detail.

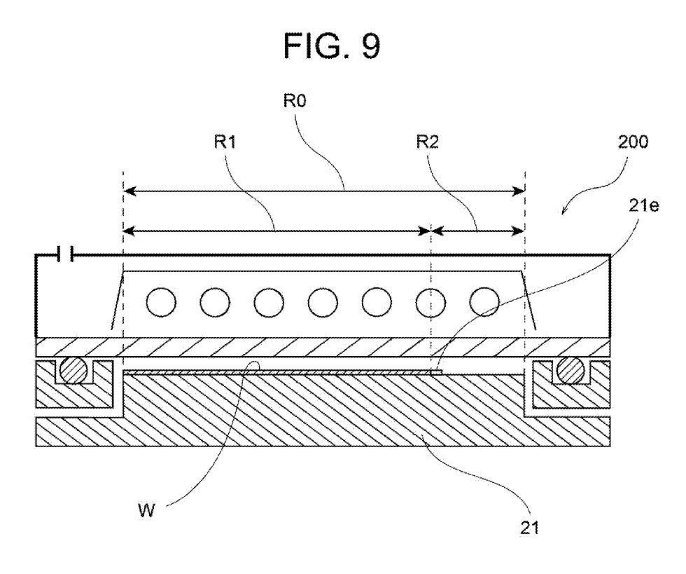

FIG. 9 is a schematic view showing an exemplary configuration of an optical processing device 200 according to the second embodiment.

The optical processing device 200 according to the second embodiment is similar to the first embodiment shown in FIG. 1, except that the optical processing device 200 differs in the formation method of the preparatory region. Thus, hereinafter, the redundant description will be omitted.

According to the second embodiment, the stage 21 is provided with a pin 21e, and this pin 21e prevents the substrate W from being placed on the right side position from the pin 21e in FIG. 9. In other words, the pin 21e forms the preparatory region that prevents the substrate W from being placed. The pin 21e also corresponds to an exemplary forming instrument (widget) according to the present invention.

As described above, when the pin 21e is provided, it makes it possible to, for example, adjust the breadth of the processing region to the size of the substrate W easier.

### Third Embodiment

Hereinafter, referring to the drawings, a third embodiment according to the present invention will be described in detail.

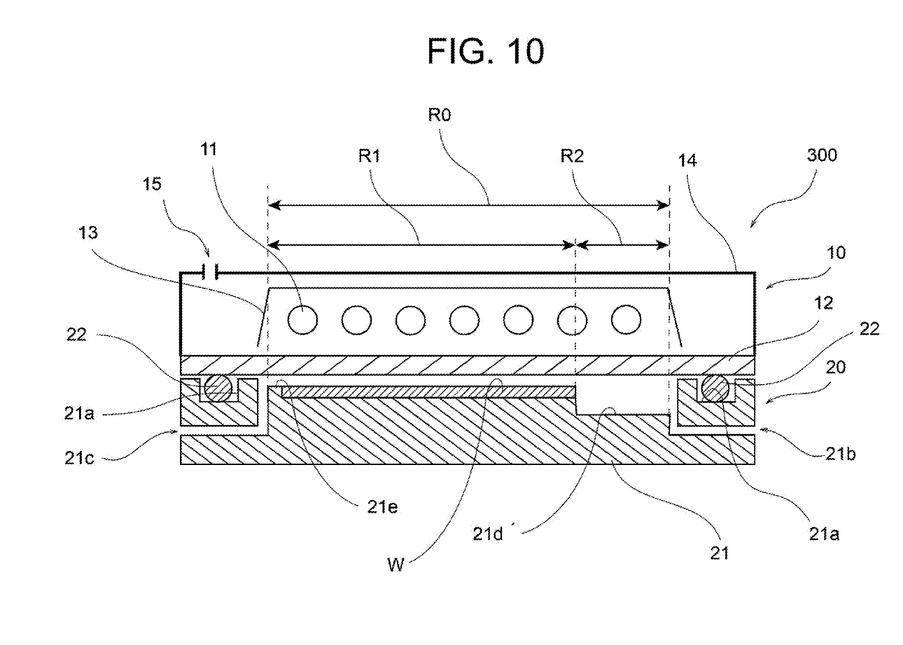

FIG. 10 is a schematic view showing an exemplary configuration of an optical processing device according to the third embodiment. The present embodiment exemplarily illustrates an application example in which the optical processing device is applied to a desmear treatment device.

### (Configuration of the Optical Processing Device)

An optical processing device 300 is provided with a processing unit 20 that holds and processes a substrate W inside thereof, and a light irradiation unit 10 that accommodates a plurality of ultra violet light sources 11 emitting, for example, ultra violet light and irradiates the substrate W of the processing unit 20 with light emitted from the ultra violet light sources 11. The light irradiation unit 10 corresponds to an example of a light source unit according to the present invention, and the processing unit 20 corresponds to an example of a processing unit according to the present invention.

Light from the ultra violet light sources 11 is irradiated onto an entire effective irradiation region R0, which corresponds to a full (maximum) width of the reflective mirror 13, almost in a uniformed manner. It should be noted that, for the sake of simplicity, the thickness of the substrate W is depicted to be larger more than a little than an actual substrate.

The light irradiation unit 10 is provided with a casing 14 in a boxed shape. On a face positioned at a lower side of the casing 14, a window member 12 made of, for example, quartz glass or the like, which transmit, for example, vacuum ultra violet light, is provided airtightly. Inside the light irradiation unit 10, an inert gas, such as nitrogen gas or the like, is supplied from the supply port 15 and kept in an inert gas atmosphere. At the upper side of the ultra violet light sources 11 inside the light irradiation unit 10, a reflector (reflective) mirror 13 is provided to reflect light emitted from the ultra violet light sources 11 toward the window member 12 side. The window member 12 corresponds to an exemplary window plate according to the present invention.

The ultra violet light sources 11 emit, for example, vacuum ultra violet light (ultra violet light having a wavelength equal to or less than 200 nm), respectively, and various known lamps can be used as the ultra violet light source. For example, a xenon excimer lamp enclosing a xenon gas (wavelength of 172 nm) and a low pressure mercury lamp (wavelength of 185 nm) may be used. Amongst those lamps, for example, the xenon excimer lamp can be preferably used as the light source for the desmear treatment.

The processing unit 20 is provided with a stage 21 that suctions to hold the substrate W, which undergoes (subject to) the ultra violet light irradiation processing (e.g., desmear treatment), on the surface thereof, with the stage 21 opposing to the window member 12 of the light irradiation unit 10. At an outer circumference of the stage, an outer circumference groove 21a is provided. An O-ring 22 is sandwiched between the outer circumference groove 21a and the window member 12 of the light irradiation unit 10 so that the light irradiation unit 10 and the processing unit 20 are assembled airtightly. A thermal resistance heater, which is not shown in the drawings, is incorporated into the stage 21, and heats the stage with the substrate W entirely (in whole) during the desmear treatment.

At one side edge portion of the stage 21 (the right side in FIG. 10), a gas inlet port 21b for supplying the processing (treatment) gas is provided, and at the other side edge portion of the stage 21 (the left side in FIG. 10), a gas outlet port 21c is provided. Although, in FIG. 10, one gas inlet port 21b and one gas outlet port 21c only are illustrated, a plurality of gas inlet ports 21b and a plurality of gas outlet ports 21c are arranged at the stage 21, respectively. A plurality of gas inlet ports 21b are aligned in the direction perpendicular to the paper surface of FIG. 10. Likewise, a plurality of gas outlet ports 21c are aligned in the direction perpendicular to the paper surface of FIG. 10. Respective gas inlet ports 21b are connected to a processing gas supply unit (not shown) and are supplied with the processing gas, respectively. Also, respective gas outlet ports 21c are connected to a gas exhaust unit (not shown).

Here, the processing gas may be considered to include, for example, an oxygen gas, a mixed gas of oxygen and ozone or watery vapor, a gas in which an inert gas or the like is mixed with those gases. According to the present embodiment, the oxygen gas is assumed to be used. During the substrate W is being irradiated with the ultra violet light from the light irradiation unit 10, the processing gas is supplied from the gas inlet port 21b and then discharged from the gas outlet port 21c. The processing gas moving from the gas inlet port 21b toward the gas outlet port 21c is assumed to flow between the window member 21 and the substrate W from the right side to the left side in FIG. 10.

According to the third embodiment, the stage 21 is provided with a stepped portion (level difference) 21d′ in an upstream side region R2 (right side in FIG. 10) with respect to the flow of the processing gas. The substrate W is prevented from being placed in the region R2 on the stage 21 by the stepped portion 21d′. The stage 21 is provides with a protrusion (projection) 21e at the gas outlet port 21c side. The substrate W is placed on the stage 21 such that the substrate W is butted against the protrusion 21e.

Hereinafter throughout the specification, amongst regions on the stage 21, in some cases, the region R1, which places and processes the substrate W, may be referred to as a processing (treatment) region R1, and the region R2, which prevents the substrate W from being placed, may be referred to as a preparatory region R2. This kind of processing region R1 corresponds to an exemplary processing region according to the present invention. Likewise, the preparatory region R2 corresponds to an exemplary preparatory region according to the present invention.

According to the third embodiment, an upper face of the stepped portion 21d′ constitutes a bottom face of the preparatory region R2. The bottom face thereof is positioned at a position distant from the light irradiation unit 10 as compared to a surface of the substrate W opposing to the light irradiation unit 10. In other words, amongst the processing region R1 and the preparatory region R2, the preparatory region R2 is assumed to be wider in the up and down (vertical) direction in the drawings (that is, the direction perpendicular to the flow of the processing gas). For this reason, the flow rate of the processing gas in the preparatory region R2 is faster than the flow rate of the processing gas in the processing region R1.

According to the third embodiment, the structure of the substrate, the procedure of the desmear treatment, and an action of the desmear treatment are similar to those in the first embodiment, which has been described above in referring to FIGS. 2 to 6. Thus, the redundant description will be omitted.

It should be noted that, however, according to the third embodiment, the distance between the window member 12 and the substrate W shown in FIG. 10 may be, for example, preferably equal to or less than 1.0 mm, more preferably equal to or less than 0.5 mm in particular, and the most preferably approximately 0.3 mm. With the distance being so set, it makes it possible to produce the oxygen radical or the ozone in a stable manner as well as to allow the vacuum ultra violet light reaching to the surface of the substrate W to have the sufficiently high intensity (that is, amount of light).

### (Action in Preparatory Region)

In the meantime, in the conventional light processing device, it is assumed to be of importance to efficiently use the ultra violet light radiated from the light irradiation unit 10. For this reason, in general, a region irradiated with the ultra violet light having the radiation (radiative) intensity effective for the processing is required to cover the entire substrate W. Nevertheless, the conventional optical processing device is not set to irradiate a region broader than the entire substrate W.

For this reason, in the conventional optical processing device, it is considered that, in a peripheral region close to the gas inlet port, before the active species having a sufficient concentration is produced by the ultra violet light, the active species is swept away toward the downstream side by the newly supplied processing gas. For this reason, in the peripheral region, it is assumed that the active species reaching to the via hole has the lower concentration, the processing speed of the desmear treatment becomes lower than in an inner region positioned at the downstream side of the processing gas. As a result, it is assumed that the processing (treatment) non-uniformity occurs in the substrate.

In contrast, according to the optical processing device 300 shown in FIG. 10, in the preparatory region R2 in which the stepped portion 21d′ is provided on the stage 21, the substrate W is prevented from being placed thereon. The preparatory region R2 is also irradiated with the light similarly to the processing region R1.

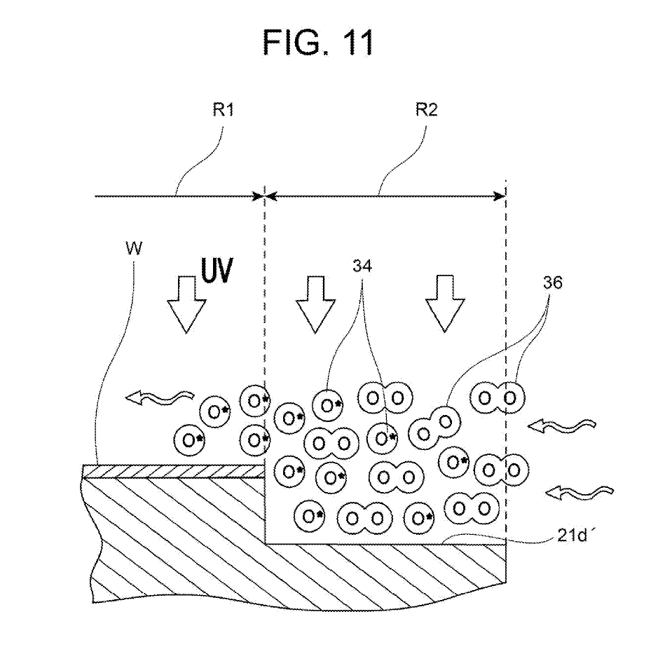

FIG. 11 is a view showing an action in the preparatory region according to the third embodiment.

In the preparatory region R2 in which the stepped portion 21d′ is provided on the stage 21, the treatment gas 36, such as oxygen gas, is irradiated with the ultra violet light from the light irradiation unit so as to produce the active species 34 such as the ozone or the oxygen radical.

Because the preparatory region R2 does not place the substrate W (in other words, does not have the smear), while the produced active species 34 is pushed by the newly supplied processing gas 36 and swept away toward the downstream side, the concentration of the active species is gradually increased so as to be stabilized. In other words, the preparatory region R2 is a region that functions to stabilize the concentration of the active species 34 with the processing gas 36 being irradiated with the ultra violet light.

Furthermore, according to the third embodiment, as the preparatory region R2 has a deeper bottom as compared to the processing region R1, the flow rate of the processing gas passing through the preparatory region R2 is slower. For this reason, it is assumed that the treatment gas is sufficiently exposed to the light from the light irradiation unit 10 within a short distance.

On the other hand, when the preparatory region R2 has an excessively deeper bottom, then the amount of ultra violet light reaching to the vicinity of the bottom face of the preparatory region R2 becomes insufficient, and it is concerned that the concentration of the active species 34 is unlikely to increase. The inventors of the present invention has performed various experiments and calculations, and reached the conclusion that the height (vertical width) of the preparatory region R2 (in other words, the distance from the window member 12 to the stepped portion 21d′ in FIG. 10) is to be equal to or less than 10 mm, preferably equal to or less than 5 mm, more preferably approximately between 0.4 mm and 3.0 mm.

The processing gas, in which the concentration of the active species 34 is increased and stabilized in the preparatory region R2, reaches onto the substrate W and advances into the via hole, while the activity thereof being kept, so as to react with the smear and remove the smear. When the processing gas reaches onto the substrate W, the concentration of the active species 34 of the processing gas is sufficiently high and stabilized. For this reason, the processing speed in the respective positions of the substrate W is sufficiently high at any positions from the upstream side to the downstream side in the flow of the processing gas so as to prevent the processing (treatment) non-uniformity from occurring in the substrate W.

The process in the preparatory region shown in FIG. 11 corresponds to an exemplary preparatory step according to the present invention.

It should be noted that, as one example, FIG. 11 schematically illustrates a state in which oxygen is irradiated with the ultra violet light and the oxygen radical serving as the active species is produced. Nevertheless, as the active species, the ozone is also produced. Also, when the processing gas contains the ozone, the oxygen radical is also produced from the ozone by the ultra violet light irradiation. Yet also, when the processing gas contains the watery vapor or hydrogen peroxide, the hydroxyl radical serving as the active species is produced by the ultra violet light irradiation.

The action described in referring to FIG. 11 in the preparatory region R2 similarly occurs for both of those various kinds of processing gas and the active species so as to prevent the processing (treatment) non-uniformity from occurring in the substrate W.

Next, according to the third embodiment, an appropriate and preferable size of the preparatory region (in other words, the length thereof in the direction along the flow of the processing gas) will be considered and addressed.

As shown in FIG. 8, the concentration of the active species (ozone) increases as the irradiation time increases from zero seconds. As the concentration the active species increases, the extinction (annihilation) amount of the active species also increases due to the reaction between active species or the like. As a result, the concentration becomes stable at, for example, the concentration of approximately 3%. In the graph in FIG. 8, the concentration of the active species becomes stable for the irradiation time of approximately 0.5 seconds. In this regards, as a result of the earnest study and investigation by the inventors of the present invention, it has been turned out that this kind of stabilization of the concentration of the active species can be achieved with the ultra violet light irradiation of approximately 0.5 seconds and at most approximately 1.0 second, although more or less varying depending on, for example, the intensity of the ultra violet light or the temperature of the processing gas or the like.

In addition, it has been turned out that the concentration is similarly stabilized in the case of the oxygen radical as well.

Accordingly, it is preferable to set the length of the preparatory region to be the length that requires the passage (transit) time of the treatment gas equal to or greater than 0.5 seconds and equal to or less than 1.0 second depending on the flow rate of the processing gas. More particularly, in order to effectively discharge the exhaust gas generated through the processing (treatment) from the processing region R1, it is preferable to keep the flow rate of the processing gas in the processing region R1 to be high to some extent, and for example, the flow rate of 50 to 500 mm/s is employed.

Furthermore, as described above, by taking the fact into account that the distance between the window member 12 and the substrate W in the processing region preferably ranges between 1.0 mm and 0.3 mm and the distance between the window member 12 and the stepped portion 21d′ in the preparatory region R2 preferably ranges between 3.0 mm and 0.4 mm, it is turned out that the length of the preparatory region is sufficient to be a short distance equal to or less than 200 mm under a typical condition.

In other words, in the processing region, by setting the distance between the window member 12 and the substrate W to be narrower, it makes it possible to maintain the higher flow rate that can achieve the faster gaseous exchange (that is, removal of the exhaust gas and the supply of the new active species) on the substrate W. On the other hand, in the preparatory region, by setting the distance between the window member 12 and the stepped portion 21d′ to be longer than the distance between the window member 12 and the substrate W, it makes it possible to achieve the slower flow rate, which enables to irradiate the processing gas 36 with the light for a long time so as to produce sufficient amount of active species, without the preparatory region being longer (that is, making the device larger in size).

### Fourth Embodiment

Hereinafter, next, a fourth embodiment of the present invention will be described in detail referring to the drawings.

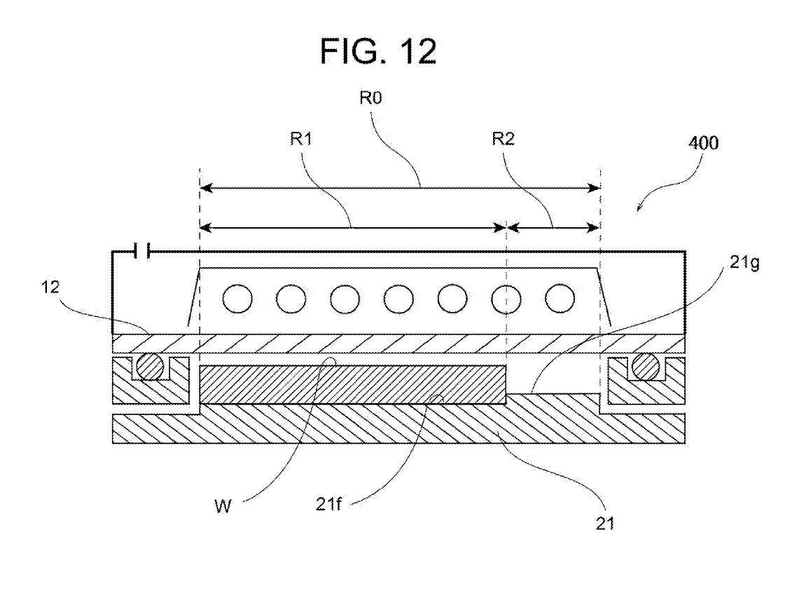

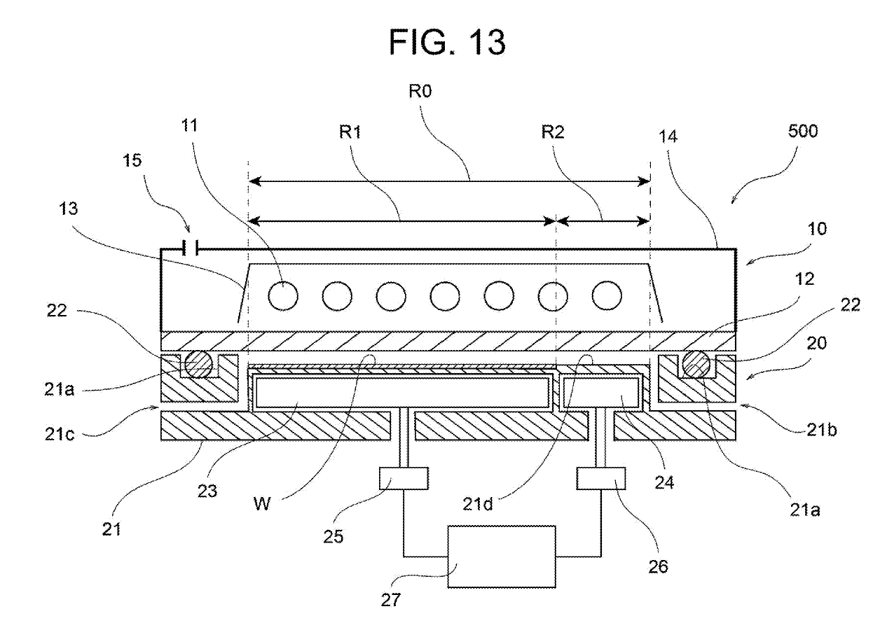

FIG. 12 is a schematic view showing a configuration of an optical processing device according to the fourth embodiment.

The optical processing device 400 according to the fourth embodiment is similar to the third embodiment shown in FIG. 10 except that the stage 21 in the preparatory region differs in the structure. Thus, the redundant description will be omitted. It should be noted that, also in FIG. 12, for the sake of the simplicity, the thickness of the substrate W is depicted to be larger more than a little than an actual substrate.

As the multilayer wiring substrate, in some cases, a thick substrate having the thickness exceeding 2 mm is to be processed. According to the second embodiment, it is presumed to process such thick substrate W.

On the other hand, according to the fourth embodiment, a surface 21f of the stage 21 in the processing region R1 is positioned at a position lower than a surface 21g of the stage 21 in the preparatory region R2 (that is, a lower position in the drawings). The substrate W is placed on the lower surface 21f, and the substrate W is prevented from being placed on the higher surface 21g.

As described above, according to the fourth embodiment, although the surface 21g of the stage 21 in the preparatory region R2 is high, when comparing the height (width) in the vertical direction between the processing region R1 and the preparatory region R2, similarly to the third embodiment, the preparatory region R2 is set to be larger (wider) in height than the processing region R1. For this reason, according to the fourth embodiment, as described above referring to FIG. 11, the concentration of the active species is also increased and stabilized in the preparatory region R2. As a result, it makes it possible to prevent the processing (treatment) non-uniformity in the substrate W, and also to keep the length of the preparatory region R2 to be sufficiently short.

### Fifth Embodiment

Hereinafter, next, referring to the drawings, a fifth embodiment of the present invention will be described in detail.

FIG. 13 is a schematic view showing an exemplary configuration of an optical processing device according to the fifth embodiment. The present embodiment exemplarily illustrates an application example in which the optical processing device is applied to a desmear treatment device.

### (Configuration of the Optical Processing Device)

An optical processing device 500 is provided with a processing unit 20 that holds and processes a substrate W inside thereof, and a light irradiation unit 10 that accommodates a plurality of ultra violet light sources 11 emitting, for example, ultra violet light and irradiates the substrate W of the processing unit 20 with light emitted from the ultra violet light sources 11. The light irradiation unit 10 corresponds to an example of a light source unit according to the present invention, and the processing unit 20 corresponds to an example of a processing unit according to the present invention.

The light irradiation unit 10 is provided with a casing 14 in a boxed shape. On a face positioned at a lower side of the casing 14, a window member 12 made of, for example, quartz glass or the like, which transmits, for example, vacuum ultra violet light, is provided airtightly. Inside the light irradiation unit 10, an inert gas, such as nitrogen gas or the like, is supplied from the supply port 15 and kept in an inert gas atmosphere. At the upper side of the ultra violet light sources 11 inside the light irradiation unit 10, a reflector (reflective) mirror 13 is provided to reflect light emitted from the ultra violet light sources 11 toward the window member 12 side. Light from the ultra violet light sources 11 is irradiated onto an entire effective irradiation region R0, which corresponds to a full (maximum) width of the reflective mirror 13, almost in a uniformed manner.

It should be noted that the reflector mirror 13 may not be necessarily an independent mechanism from the ultra violet light source. For example, the ultra violet light source itself may have an ultra violet reflective structure.

The ultra violet light sources 11 emit, for example, vacuum ultra violet light (ultra violet light having a wavelength equal to or less than 220 nm), respectively, and various known lamps can be used as the ultra violet light source. For example, a xenon excimer lamp enclosing a xenon gas (wavelength of 172 nm) and a low pressure mercury lamp (wavelength of 185 nm) may be used. Amongst those lamps, for example, the xenon excimer lamp can be preferably used as the light source for the desmear treatment.

The processing unit 20 is provided with a stage 21 which suctions to hold the substrate W, which undergoes (subject to) the ultra violet light irradiation processing (e.g., desmear treatment), on the surface thereof, with the stage 21 opposing to the window member 12. The stage 21 has, for example, a suction hole (not shown) bored on the stage 21, in order to suction the substrate W. According to the present embodiment, the stage 21 is formed by, for example, an aluminum material in order to assure the flatness thereof or an accuracy of the suction hole. The stage 21 corresponds to an exemplary stage according to the present invention. At an outer circumference of the stage, an outer circumference groove 21a is provided. An O-ring 22 is sandwiched between the outer circumference groove 21a and the window member 12 of the light irradiation unit 10 so that the light irradiation unit 10 and the processing unit 20 are assembled airtightly.

It is assumed that an adjustment mechanism (not shown) is provided that makes fine adjustment to the height of the stage 21 to adjust the distance between the substrate W and the window member 12 with a higher accuracy as long as the airtightness of the O-ring 22 is not deteriorated.

At one side edge portion of the stage 21 (the right side in FIG. 13), a gas inlet port 21b for supplying the processing gas is provided, and at the other side edge portion of the stage 21 (the left side in FIG. 13), a gas outlet port 21c is provided. Although, in FIG. 13, one gas inlet port 21b and one gas outlet port 21c only are illustrated, a plurality of gas inlet ports 21b and a plurality of gas outlet ports 21c are arranged at the stage 21, respectively. A plurality of gas inlet ports 21b are aligned in the direction perpendicular to the paper surface of FIG. 13. Likewise, a plurality of gas outlet ports 21c are aligned in the direction perpendicular to the paper surface of FIG. 13. Respective gas inlet ports 21b are connected to a processing gas supply unit (not shown) and are supplied with the processing gas, respectively. Also, respective gas outlet ports 21c are connected to a gas exhaust unit (not shown).

Here, the processing gas may be considered to include, for example, an oxygen gas, a mixed gas of oxygen and ozone or watery vapor, a gas in which an inert gas or the like is mixed with those gases. According to the present embodiment, the oxygen gas is assumed to be used. During the substrate W is being irradiated with the ultra violet light from the light irradiation unit 10, the processing gas is supplied from the gas inlet port 21b and then discharged from the gas outlet port 21c. The processing gas moving from the gas inlet port 21b toward the gas outlet port 21c is assumed to flow between the window member 21 and the substrate W from the right side to the left side in FIG. 13.

The stage 21 is provided with a convex portion 21d in an upstream side region R2 (right side in FIG. 13). The substrate W is prevented from being placed in the region R2 on the stage 21 by the convex portion 21d. In other words, a stepped portion (level difference) is formed on the stage 21 by the region R1, which places and holds the substrate W, and the region R2, which prevents the substrate W from being placed.

Hereinafter throughout the specification, amongst regions on the stage 21, in some cases, the region R1, which places and processes the substrate W, may be referred to as a processing (treatment) region R1, and the region R2, which prevents the substrate W from being placed, may be referred to as a preparatory region R2. The processing region R1 corresponds to an exemplary processing region according to the present invention. The preparatory region R2 corresponds to an exemplary preparatory region according to the present invention.

According to the fifth embodiment, a first heater 23 is incorporated into the processing region R1 of the stage 21, and a second heater 24 is incorporated into the preparatory region R2 of the stage 21. The first heater 23 heats the processing region R1 with the substrate W in whole, and the second heater 24 heats the preparatory region R2. For those heaters 23 and 24, for example, a sheathed heater or a cartridge heater may be used.

The first heater 23 is connected to a first heater controller 25 that controls the heating temperature in the processing region R1 to the preset temperature, and the second heater 24 is connected to a second heater controller 26 that controls the heating temperature in the preparatory region R2 to another preset temperature. Those heater controllers 25 and 26 control the heating temperatures independently from each other, and respective preset temperatures are set by a control unit 27.

The control unit 27 sets the preset temperature to the second heater controller 26 to the temperature lower than the preset temperature to the first heater controller 25. As a result, the temperature on a surface of the stage 21 in the preparatory region R2 is kept to be lower than the temperature on the surface of the stage 21 in the processing region R1. The first heater 23 and the second heater 24 correspond to an exemplary heating mechanism according to the present invention. A combination of the first heater controller 25, the second heater controller 26, and the control unit 27 correspond to an exemplary temperature controller according to the present invention.

It should be noted that, according to the present invention, even in the case in which a plurality of heating mechanisms are provided, each of the processing region and the preparatory region may be provided with at least one heating mechanism which is temperature controlled independently between the processing region and the preparatory region. For example, a common heater may be shared between the processing region R1 and the preparatory region R2, which commonly heats the processing region R1 and the preparatory region R2.

According to the present embodiment, a protrusion amount of the convex portion 21d (in other words, the height of the stepped portion of the stage 21) is equivalent to the thickness of the substrate W. For this reason, gaps (clearances) through which the treatment gas flows are become equivalent between the processing region R1 and the preparatory region R2 so that the flow of the processing gas from the gas inlet port 21b toward the gas outlet port 21c are stabilized.

Furthermore, the vacuum ultra violet light radiated from the light irradiation unit 10 reaches to both the processing region R1 and the preparatory region R2 with the equivalent intensity.

According to the fifth embodiment, the structure of the substrate is similar to those in the first embodiment which has been described above by referring to FIG. 2. Thus, the redundant description will be omitted.

### (Procedure of Desmear Treatment)

Next, referring back to FIG. 13, a procedure of the desmear treatment performed by the light processing device 500 will be described in detail.

First, the substrate W to be processed is conveyed from outside the processing unit 20 into the processing unit 20, and then placed on the stage 21. The substrate W is held on the stage 21 by the vacuum suction or the like. Subsequently, the processing gas is supplied from the gas inlet port 21b into the processing unit 20 by the processing gas supply unit.

Simultaneously with the supply of the processing gas, or after inside the processing chamber is completely purged by the processing gas, or alternatively until the processing gas is supplied and then inside the processing chamber is completely purged by the processing gas, the ultra violet light sources 11 are lighted up, and the ultra violet light is radiated from the irradiation unit 10 toward the processing unit 20 to irradiate the substrate W with the ultra violet light through the processing gas.

The processing gas that is irradiated with the ultra violet light produces the active species such as ozone or the oxygen radical or the like, and reacts with the smear in the via hole so as to remove the smear, which will be described in detail later. A gas of, for example, carbon dioxide, which is produced with the processing gas reacting with the smear, taps into a flow of a newly supplied processing gas, is conveyed toward the downstream side, sucked from the gas outlet port 21c, and discharged by the exhaust unit.

It should be noted that, after the irradiation of the ultra violet light, the residual active species, such as the ozone or the oxygen radical or the like, in the processing chamber, or the gas produced by the reaction, is discharged from the gas outlet port 21c by supplying the discharging (exhaust) gas from the gas inlet port 21b. This discharging gas may not be necessarily the processing gas, and may be the other gas such as nitrogen gas or the compressed air or the like.

The substrate W, after being treated (processed), is removed from the stage 21 and carried out to the outside of the processing unit 20.

### (Action of Desmear Treatment)

Hereinafter, referring to FIGS. 3 to 6, an action of the desmear treatment according to the fifth embodiment will be described in detail.

In a first phase shown in FIG. 3, the processing gas supplied from the gas inlet port is irradiated with the ultra violet light, as shown in the arrow directed downwardly from upper side in FIG. 3, so as to produce the ozone or the oxygen radical, which serves as the active species 34, from oxygen contained in the processing gas (here, only the oxygen radical is illustrated in FIG. 3). The produced active species 34 advances into the via hole 33 of the substrate W.

In a second phase shown in FIG. 4, the active species 34 reacts with the smear S in the via hole 33, and a part of the smear S is decomposed as well as a part of the smear S being decomposed with the smear S being irradiated with the ultra violet light. In addition, with the smear S being so decomposed, a reaction product gas 35 such as carbon dioxide gas or watery vapor or the like is produced.

Furthermore, according to the fifth embodiment, in order to accelerate the decomposition of the smear S, the heating temperature in the processing region R1 is controlled to be a prescribed temperature equal to or greater than 120 degrees Celsius and equal to or less than 190 degrees Celsius.

Subsequently, in a third phase shown in FIG. 5, the reaction product gas 35 is swept away from the via hole 33 toward the gas outlet port side (left side in FIG. 5) by the newly supplied processing gas containing the active species 34, which is flowing from the gas inlet port side (right side in FIG. 5). As the reaction product gas 35 is being discharged, the newly supplied processing gas containing the active species 34 advances into the via hole 33.

As a result of repeating the radiation of the ultra violet light, the advancement of the active species 34, and the discharge of the reaction product gas 35, in a final phase shown in FIG. 6, the smear S is almost completely removed in the via hole 33. The reaction product gas 35 swept away outside the via hole 33 taps into the flow of the processing gas on the substrate W and is discharged from the gas outlet port 21c shown in FIG. 13.

The processes of the optical processing shown in FIGS. 3 to 6 correspond to exemplary processes of the processing according to the present invention.

As described above, in the desmear treatment, it is of great importance in order to improve the processing efficiency that the active species, such as the oxygen radical or the ozone or the like, is produced by radiating the ultra violet light and advances into the via hole 33, as well as the ultra violet light itself is also irradiated onto the inside of the via hole 33.

For this reason, it is preferable to set the distance between the window member 12 and the substrate W shown in FIG. 13 to be, for example, equal to or less than 1 mm, and more preferably, in particular, equal to or less than 0.5 mm. With the distance so being set, it makes it possible to produce the oxygen radial or the ozone in a stable manner and also to allow the vacuum ultra violet light reaching to the surface of the substrate W to have the sufficient intensity (that is, amount of light).

### (Action in Preparatory Region)

In the meantime, in the conventional light processing device, it is assumed to be of importance to efficiently use the ultra violet light radiated from the light irradiation unit 10. For this reason, in general, a region irradiated with the ultra violet light having the radiation (radiative) intensity effective for the processing is required to cover the entire substrate W. Nevertheless, the conventional optical processing device is not set to irradiate a region broader than the entire substrate W.

For this reason, in the conventional optical processing device, it is considered that, in a peripheral region close to the gas inlet port, before the active species having a sufficient concentration is produced by the ultra violet light, the active species is swept away toward the downstream side by the newly supplied processing gas. For this reason, in the peripheral region, it is assumed that the active species reaching to the via hole has the lower concentration, the processing speed of the desmear treatment becomes lower than in an inner region positioned at the downstream side of the processing gas. As a result, it is assumed that the processing (treatment) non-uniformity occurs in the substrate.

In contrast, according to the optical processing device 500 shown in FIG. 13, the stage 21 is provides with the convex portion 21d to prevent the substrate W from being placed so as to form the preparatory region R2. The preparatory region R2 is also irradiated with the light similarly to the processing region R1.

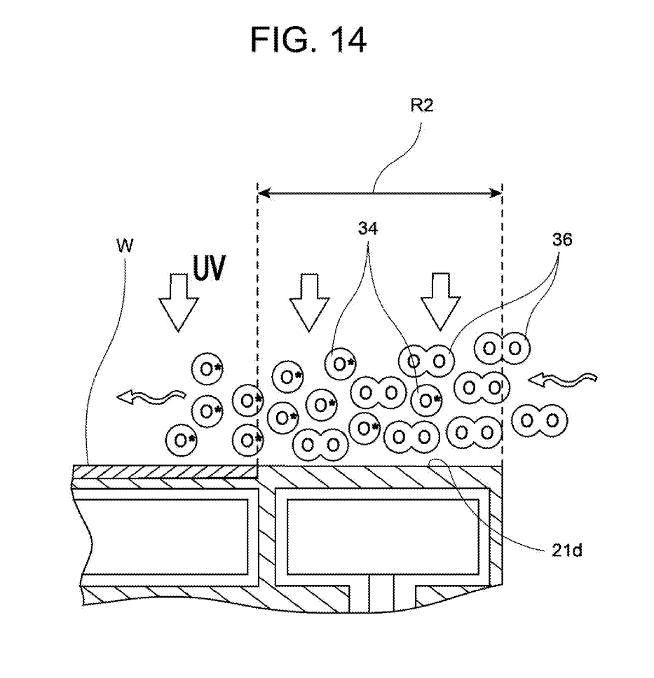

FIG. 14 is a view showing an action in the preparatory region according to the fifth embodiment.

In the preparatory region R2 formed by the convex portion 21d of the stage 21, the processing gas 36, such as oxygen gas, is irradiated with the ultra violet light from the light irradiation unit so as to produce the active species 34 such as the ozone or the oxygen radical.

Because the preparatory region R2 does not place the substrate W (in other words, does not have the smear S), while the produced active species 34 is pushed by the newly supplied processing gas 36 and swept away toward the downstream side, the concentration of the active species is gradually increased so as to be stabilized. In other words, the preparatory region R2 is a region that functions to produce the active species 34 with the treatment gas 36 being irradiated with the ultra violet light prior to the processing in the processing region (that is, active species producing region). According to the present embodiment, as the processing gas flows through the gap (clearance), which is temporally and spatially stabilized, lying between the stage and the window member, the flow of the processing gas also becomes stable. As a result, the concentration of the active species 34 is stabilized.

The processing gas, in which the concentration of the active species 34 is increased and stabilized in the preparatory region R2, reaches onto the substrate W and advances into the via hole, while the activity thereof being kept, so as to react with the smear and remove the smear. When the processing gas reaches onto the substrate W, the concentration of the active species 34 of the treatment gas is sufficiently high and stabilized. For this reason, the processing speed in the respective positions of the substrate W is sufficiently high at any positions from the upstream side to the downstream side in the flow of the processing gas so as to prevent the processing (treatment) non-uniformity from occurring in the substrate W.

The process in the preparatory region shown in FIG. 14 corresponds to an exemplary preparatory step according to the present invention.

It should be noted that, as one example, FIG. 14 schematically illustrates a state in which oxygen is irradiated with the ultra violet light and the oxygen radical serving as the active species is produced. Nevertheless, as the active species, the ozone is also produced. Also, when the processing gas contains the ozone, the oxygen radical is also produced from the ozone by the ultra violet light irradiation. Yet also, when the treatment gas contains the watery vapor or hydrogen peroxide, the hydroxyl radical serving as the active species is produced by the ultra violet light irradiation.

The action described in referring to FIG. 14 in the preparatory region R2 similarly occurs for both of those various kinds of treatment gases and the active species so as to prevent the processing non-uniformity from occurring in the substrate W.

In the meantime, although the preparatory region R2 having a sufficient area or breadth (that is, the length in the direction along the flow) is desirable in order to increase and stabilize the concentration of the active species 34, excessively broad preparatory region R2 may necessarily entails a large sized device.

To cope with above circumstance, according to the fifth embodiment, the heating temperatures of the first heater 23 and the heating temperature of the second heater 24 are controlled to be different temperatures from each other. In this regard, in particular, the temperature of the preparatory region R2 (the temperature on the surface of the stage 21) is set to be lower than the temperature of the processing region R1 (the temperature on the surface of the stage 21). In this way, with the temperature of the preparatory region R2 being lower, it makes it possible to suppress the thermal decomposition of the active species 34, which is produced in the preparatory region R2, so as to increase the concentration of the active species 34 in a short period of time (in other words, in the preparatory region R2 with a short distance).

Hereinafter, the relationship between the temperature of the preparatory region R2 and an increase in concentration of the active species 34 will be described below.

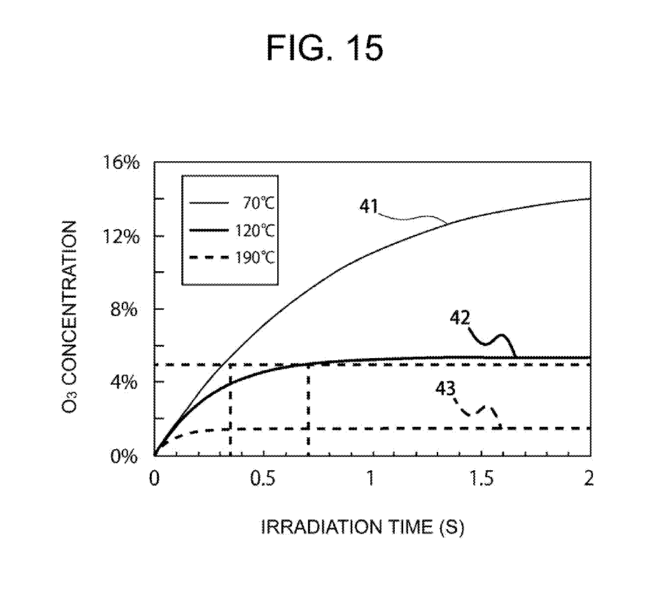

FIG. 15 shows a graph representing the relationship between the irradiation of the ultra violet light and the concentration of the active species at a plurality of temperatures.

In FIG. 15, the horizontal axis of the graph denotes the irradiation time of the ultra violet light, and the vertical axis of the graph denotes the concentration of ozone as the active species.

In an example shown in FIG. 15, oxygen is used as the processing gas, and the vacuum ultra violet light having the wavelength of 172 nm is used as the ultra violet light with the intensity of 250 mW/cm².

Also, a thin solid line 41 shown in FIG. 15 denotes the change in concentration of the active species (ozone) when the preparatory region R2 is at 70 degrees Celsius, a bold solid line 42 denotes the change in concentration of the active species (ozone) when the preparatory region R2 is at 120 degrees Celsius, and a dashed line 43 denotes the change in concentration of the active species (ozone) when the preparatory region R2 is at 190 degrees Celsius.

The concentration of the active species (ozone) increases as the irradiation time increases from zero seconds. As the concentration the active species increases, the extinction (annihilation) amount of the active species also increases due to the reaction between active species or the like.

The extinction amount is larger as the temperature of the preparatory region is higher. For this reason, while it takes approximately 0.7 seconds until reaching to the concentration of 5% when the preparatory region is at 120 degrees Celsius, it takes approximately 0.35 seconds, which is nearly half, until reaching to the concentration of 5% when the preparatory region is at 70 degrees Celsius. Furthermore, when the preparatory region is at 190 degrees Celsius, as the extinction amount is larger, it is observed that the upper limit of the concentration of the active species is less than 2%.

As described above, the concentration of the active species becomes higher as the temperature of the preparatory region becomes lower, which is preferable for the ultra violet light irradiation processing (e.g., desmear treatment). However, in the case of, for example, ozone, when the temperature of the preparatory region becomes less than 50 degrees Celsius, then the concentration exceeds 10% and it may cause an explosion.

In order to avoid this circumstance, it is preferable to set the temperature of the preparatory region to be equal to or greater than 50 degrees Celsius. It should be noted that, as the reactivity of the processing gas becomes higher as the ozone concentration is higher, it is preferable that the ozone concentration is closer to 10% unless the ozone concentration exceeds 10%.

Although an increase in the concentration of the active species may vary more or less depending on, for example, the intensity of the ultra violet light or the like, as a result of the earnest study or investigation by the inventors of the present invention, it has been turned out that a sufficient concentration of the active species is achieved with the irradiation of the ultra violet light for approximately 0.25 seconds and the irradiation of the ultra violet light for at most approximately 1 second may suffice, as long as the temperature in the preparatory region is at a prescribed temperature equal to or greater than 50 degrees Celsius and equal to or less than 190 degrees Celsius and lower than the processing region.

In addition, taking the achieving concentration of the active species as shown in FIG. 15 into consideration, it is more preferable that the temperature of the preparatory region is equal to or greater than 50 degrees Celsius and equal to or less than 120 degrees Celsius.

Yet also, it is turned out that the sufficient concentration can be obtained in the nearly equal time in either ozone or the oxygen radical.

Accordingly, it is preferable to set the length of the preparatory region to be the length that requires the passage (transit) time of the treatment gas equal to or greater than 0.25 seconds and equal to or less than 1.0 second depending on the flow rate of the processing gas. In order to avoid the obstruction by the reaction product (that is, lowering of the reaction speed), it is preferable to keep the flow rate of the treatment gas to be high to some extent, and for example, the flow rate of 50 to 500 mm/s is employed. Thus, it is assumed that the length of the preparatory region has preferably approximately 13 to 500 mm.

### Sixth Embodiment

Hereinafter, a sixth embodiment of the present invention will be described in detail.

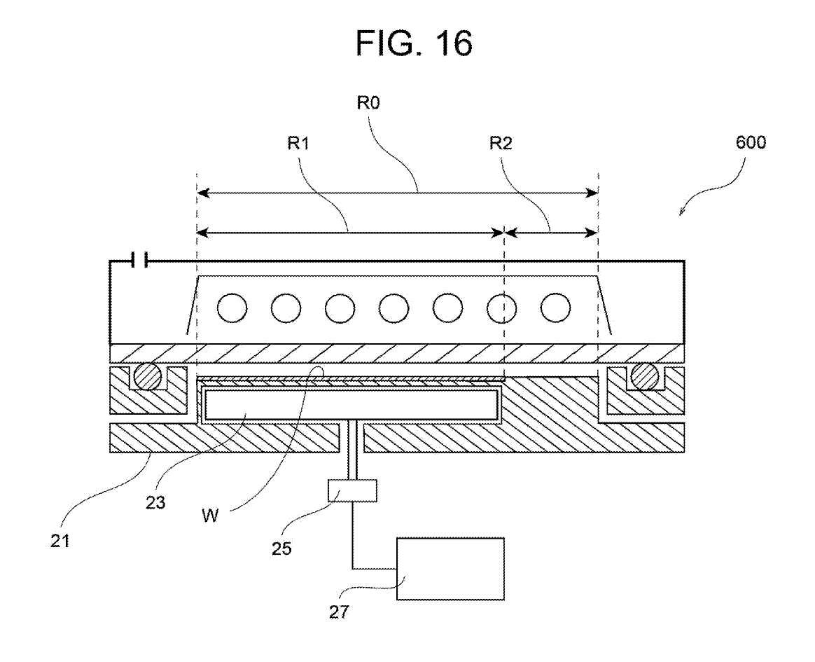

FIG. 16 is a schematic view showing an optical processing device according to the sixth embodiment.

The optical processing device 600 according to the sixth embodiment is similar to the fifth embodiment shown in FIG. 13 except that the sixth embodiment differs in the arrangement of the heater. Thus, redundant description will be omitted.

According to the sixth embodiment, in the stage 21, while the heater 23 is incorporated into the processing region R1, the heater is not incorporated into the preparatory region R2. The heater 23 of the processing region R1 is connected to a heater controller 25, and the heater controller 25 controls the heating temperature of the heater 23 to the preset temperature, which is set by the control unit 27.

In the processing region R1, the surface of the stage and the substrate W suctioned and held on the stage surface reaches to the temperature that is close to the preset temperature set by the control unit 27 by directly heating by the heater 23.

On the other hand, the preparatory region R2 is indirectly heated solely by the heat transmitted from the processing region R1 through the heat conduction by the stage 21. As a result, the temperature of the surface of the stage 21 in the preparatory region R2 is kept lower than the temperature of the surface of the stage 21 in the processing region R1 in an assured manner. Accordingly, it makes it possible to sufficiently increase the concentration of the active species in a short period of time (in other words, with a short distance) in the preparatory region R2.

### Seventh Embodiment

Hereinafter, a seventh embodiment of the present invention will be described in detail.

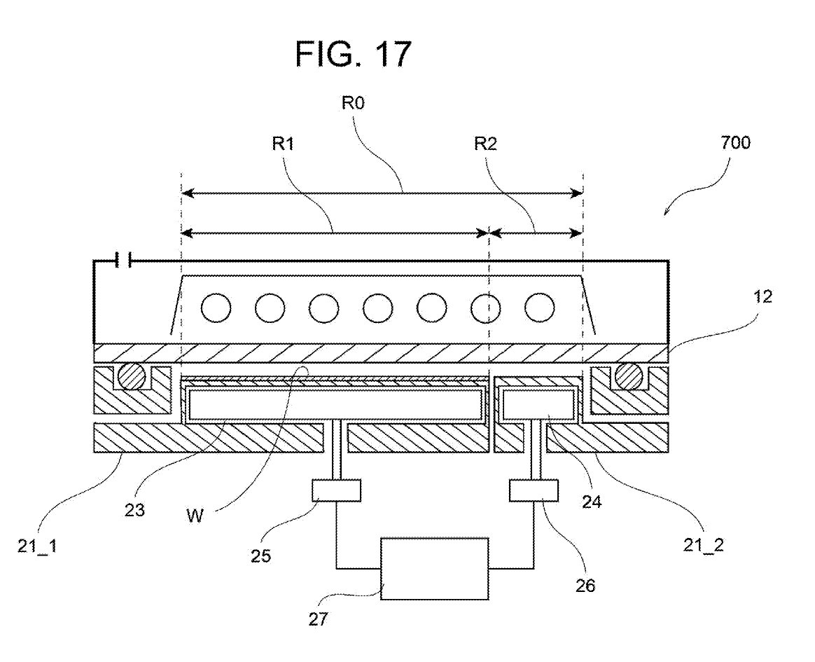

FIG. 17 is a schematic view showing an optical processing device according to the seventh embodiment.

The optical processing device 600 according to the seventh embodiment is similar to the fifth embodiment shown in FIG. 13 except that the seventh embodiment differs in the structure of the stage. Thus, redundant description will be omitted.

According to the seventh embodiment, a stage is separated into a first stage 21_1 having the processing region R1 and a second stage 21_2 having the preparatory region R2. The first stage 21_1 is formed by, for example, an aluminum material in order to assure the flatness or the accuracy of the suction hole. On the other hand, the second stage 21_2 may be formed by, for example, a stainless steel material (SUS) or the like as the higher accuracy, which is otherwise required for the first stage 21_1, is not necessarily required.

Furthermore, the first stage 21_1 has a structure movable in the vertical direction in order to adjust the distance between the substrate W and the window member 12 with the higher accuracy with the height thereof being fine adjusted by the adjustment mechanism (not shown). On the other hand, the second stage 21_2 has a simplified structure of which height is fixed.

A first heater 23 is incorporated into the first stage 21_1, and a second heater 24 is incorporated into the second stage 21_2. The first heater 23 heats the processing region R1 with the substrate W in whole, and the second heater 24 heats the preparatory region R2.

Similarly to the fifth embodiment shown in FIG. 13, according to the seventh embodiment, the first heater 23 is connected to a first heater controller 25, and the second heater 24 is connected to a second heater controller 26. A control unit 27 controls the preset temperature for the second heater controller 26 to be lower than the preset temperature for the first heater controller 25. As a result, the temperature on the surface of the stage in the preparatory region R2 is kept lower than the temperature on the surface of the stage in the processing region R1 so as to sufficiently increase the concentration of the active species in a short period of time (in other words, with a short distance) in the preparatory region R2.

Yet furthermore, according to the seventh embodiment, a gap is provided between the first stage 21_1 and the second stage 21_2 in order to avoid the heat conduction from the first stage 21_1 to the second stage 21_2. With the gap being provided, it makes it possible to allow the temperature control of the first stage 21_1 and the second stage 21_2 to be highly independent from each other and to allow the heating temperature in the respective regions to be controlled easier. It should be noted that the gap between the first stage 21_1 and the second stage 21_2 is sealed off by, for example, a packing or the like in order to prevent the processing gas from leaking.

### Eighth Embodiment

Hereinafter, an eighth embodiment of the present invention will be described in detail.

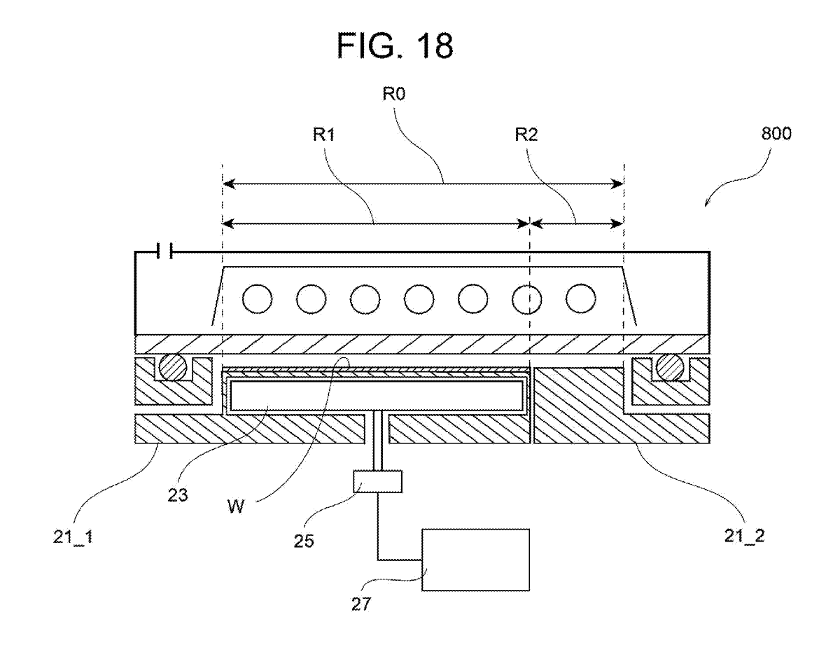

FIG. 18 is a schematic view showing an optical processing device according to the eighth embodiment.

The optical processing device 800 according to the eighth embodiment is similar to the seventh embodiment except that the eighth embodiment differs in the arrangement of the heater. Thus, a redundant description will be omitted.

According to the eighth embodiment, while a heater 23 is incorporated into the first stage 21_1, a heater is not incorporated into the second stage 21_2. The heater 23 of the first stage 21_1 is connected to a heater controller 25, and the heater controller 25 controls the heating temperature of the heater 23 to be the preset temperature set by a control unit 27.

A surface of the first stage 21_1 and the substrate W suctioned and held on the surface of the stage reaches to the temperature close to the preset temperature set by the control unit 27 by directly heating by the heater 23. On the other hand, the preparatory region R2 is solely indirectly heated by the radiant (radiation) heat from the first stage 21_1. As a result, the temperature on the surface of the stage in the preparatory region R2 is kept lower than the temperature on the surface of the stage in the processing region R1 in an assured manner so as to sufficiently increase the concentration of the active species in a short period of time (in other words, with a short distance) in the preparatory region R2.

### WORKING EXAMPLES

Hereinafter, experimental examples carried out in order to confirm advantageous effects of the above mentioned embodiments will be described in detail.

### Working Example 1

Referring to the configuration shown in FIG. 1, an optical processing device according to the first embodiment having the following specification was fabricated.

### [Stage 21]

Dimension: 755×650 mm, Thickness: 20 mm

Material: Aluminum

Length of Preparatory Region: 100 mm

Heating Temperature: 150 degrees Celsius

### [Ultra Violet Light Source 11]

Xenon Excimer Lamp

Light Emission Length: 700 mm

Width: 70 mm

Input Power: 500 W

Number of Lamps: 7

Irradiation Time of Vacuum Ultra Violet Light: 300 seconds

### [Window Member 12]

Dimension: 755×650 mm, Thickness 5 mm

Material: Quartz Glass

Distance between Window Member and Substrate: 0.3 mm

### [Substrate W]

Structure: Fabricated by layering in insulating layer on a copper substrate and forming a via hole in the insulating layer

Dimension: 500 mm×500 mm×0.5 mm

Thickness of Insulating Layer: 30 μm

Diameter of Via Hole: 50 μm

### [Condition of Processing (Treatment) Gas or the Like]

Processing Gas: Oxygen Concentration 100%

Flow Rate of Processing Gas: 1.0 L/min

According to the optical processing unit having the above mentioned specification, it took approximately 0.9 seconds for the processing gas to pass through the preparatory region, and the processing (treatment) non-uniformity was not observed in the substrate W.

### Working Example 2

Referring to the configuration shown in FIG. 10, an optical processing device according to the third embodiment having the following specification was fabricated.

### [Stage 21]

Dimension: 755×650 mm, Thickness: 20 mm

Material: Aluminum

Height of Preparatory Region: 1.0 mm

Length of Preparatory Region: 40 mm

Heating Temperature: 150 degrees Celsius

### [Ultra Violet Light Source 11]

Xenon Excimer Lamp

Light Emission Length: 700 mm

Width: 70 mm

Input Power: 500 W

Number of Lamps: 7

Irradiation Time of Vacuum Ultra Violet Light: 300 seconds

### [Window Member 12]

Dimension: 755×650 mm, Thickness 5 mm

Material: Quartz Glass

Distance between Window Member and Substrate: 0.3 mm

### [Substrate W]

Structure: Fabricated by layering in insulating layer on a copper substrate and forming a via hole in the insulating layer

Dimension: 500 mm×500 mm×0.5 mm

Thickness of Insulating Layer: 30 μm

Diameter of Via Hole: 50 μm

[Condition of Processing Gas or the like]

Processing Gas: Oxygen Concentration 100%

Flow Rate of Processing Gas: 1.0 L/min

According to the optical processing unit having the above mentioned specification, it took approximately 1.2 seconds for the processing gas to pass through the preparatory region, and the processing (treatment) non-uniformity was not observed in the substrate W.

### Working Example 3

Referring to the configuration shown in FIG. 13, an optical processing device according to the fifth embodiment having the following specification was fabricated.

### [Stage 21]

Dimension: 755×650 mm, Thickness: 20 mm

Material: Aluminum

Length of Preparatory Region: 40 mm

Heating Temperature of Processing Region: 150 degrees Celsius

Heating Temperature of Preparatory Region: 70 degrees Celsius

### [Ultra Violet Light Source 11]

Xenon Excimer Lamp

Light Emission Length: 700 mm

Width: 70 mm

Input Power: 500 W

Number of Lamps: 7

Irradiation Time of Vacuum Ultra Violet Light: 300 seconds

### [Window Member 12]

Dimension: 755×650 mm, Thickness 5 mm

Material: Quartz Glass

Distance between Window Member and Substrate: 0.3 mm

### [Substrate W]

Structure: Fabricated by layering in insulating layer on a copper substrate and forming a via hole in the insulating layer

Dimension: 500 mm×500 mm×0.5 mm

Thickness of Insulating Layer: 30 μm

Diameter of Via Hole: 50 μm

[Condition of Processing Gas or the like]

Processing Gas: Oxygen Concentration 100%

Flow Rate of Processing Gas: 1.0 L/min

According to the optical processing unit having the above mentioned specification, the processing gas passed through the preparatory region having the short length of 40 mm in a short period of time of approximately 0.35 seconds. Nevertheless, the concentration of the active species was sufficiently high, and the processing (treatment) non-uniformity was not observed in the substrate W.

It should be noted that, although in the above mentioned description, certain application examples to the desmear treatment device are described as examples of the optical processing device according to the present invention, the optical processing device according to the present invention is not limited to those described and may be applied to, for example, an optical asking treatment device or a removal treatment device for a resist or a dry cleaning treatment device or the like.

Furthermore, although in the above mentioned description, a certain type of stage 21 provided with the forming instrument according to the present invention is exemplarily described, the placing base or the processing unit according to the present invention may not be provided with the forming instrument.

Yet furthermore, although in the above mentioned description, a certain example in which the convex portion 21e prevents the substrate W from being placed in the preparatory region is exemplarily described, the preparatory region according to the present invention is not limited to those described. For example, the preparatory region according to the present invention may be a region in which the substrate W is prevented from being placed by placing a dummy plate having the thickness identical to the substrate W, or alternatively a region in which the substrate W is prevented from being placed by a pin or the like arranged in the boundary between the processing region and the preparatory region.

Although specific embodiments are described above, these embodiments are merely illustrative in nature and are not intended to limit the scope of the present invention. The apparatuses and the methods described in the present specification can be implemented in embodiments aside from those described above. Omissions, substitutions, and modifications can be made, as appropriate, to the embodiments described above without departing from the scope of the present invention. An embodiment with such omissions, substitutions, and modifications is encompassed by what is described in the claims and any equivalent thereof and falls within the technical scope of the present invention.

The present application is based on Japanese Patent Application No. 2015-022099 (filed on Feb. 6, 2015), Japanese Patent Application No. 2015-029895 (filed on Feb. 18, 2015), and Japanese Patent Application No. 2015-104673 (filed on May 22, 2015) and claims the priority based on the above Japanese Patent Applications. All those disclosed in the above Japanese Patent Applications are hereby incorporated into the present application by reference.

### REFERENCE SIGNS LIST

100: Optical Processing Device
W: Substrate
10: Light Irradiation Unit
11: Ultra Violet Light Source
12: Window Member
21: Stage
23, 24: Heater
25, 26: Heater Controller
27: Control Unit
R1: Processing Region
R2: Preparatory Region

What is claimed is:

1. An optical processing device, comprising:
a light source unit configured to emit light; and
a processing unit configured to expose an object to be processed to the light emitted from the light source unit,
the processing unit includes:
a processing region in which the object to be processed is held and exposed to the light in an atmosphere of a processing gas; and
a preparatory region through which the processing gas passes, while being exposed to the light, to move toward the processing region, the preparatory region being configured to prevent the object to be processed from being arranged thereon.

2. The optical processing device according to claim 1, wherein the processing unit includes:
a placing base configured to place the object to be processed thereon; and
a forming instrument configured to prevent the object to be processed from being placed on a part of the placing base to form the preparatory region.

3. The optical processing device according to claim 1 or claim 2, wherein
the light source unit is provided with a window plate configured to transmit light,
the processing unit is provided with a placing base opposing to the window plate and configured to place the object to be processed thereon, and
the preparatory region is a region lying between the window plate and a part of the placing base on which the object to be processed is not placed.

4. The optical processing device according to any one of claims 1 to 3, wherein
in the preparatory region, a bottom face thereof opposing to the light source unit is distant from the light source unit as compared to a surface of the object to be processed opposing to the light source unit.

5. The optical processing device according to claim 4, wherein
the preparatory region has a flow channel cross sectional area that is larger than that of the processing region.

6. The optical processing device according to any one of claims 1 to 5, wherein
the light emitted from the light source unit is ultra violet light,
in the processing region, the object to be processed is held, while being heated, and exposed to the ultra violet light in the atmosphere of the processing gas, and wherein
the optical processing device further comprises:
a temperature control unit configured to control heating temperature at least in the processing region to allow temperature in the preparatory region to be lower than temperature in the processing region.

7. The optical processing device according to claim 6, wherein
the processing unit further comprises:
a stage having the processing region and the preparatory region and being formed integrally; and
a plurality of heating mechanisms provided at the processing region and the preparatory region, respectively, and respective heating temperatures of the heating mechanisms are controlled by the temperature control unit independently from each other between the processing region and the preparatory region.

8. The optical processing device according to claim 6, wherein
the processing unit further comprises:
a stage having the processing region and the preparatory region and being formed integrally; and
a heating mechanism provided solely at the processing region, and heating temperature of the heating mechanism is controlled by the temperature control unit.

9. The optical processing device according to claim 6, wherein
the processing unit further comprises:
a first stage having the processing region;
a second stage having the preparatory region and separated from the first stage; and
a plurality of heating mechanisms provided at the processing region and the preparatory region, respectively, and respective heating temperatures of the heating mechanisms are controlled by the temperature control unit independently from each other between the processing region and the preparatory region.

10. The optical processing device according to claim 6, wherein
the processing unit further comprises:
a first stage having the processing region;
a second stage having the preparatory region and separated from the first stage; and
a heating mechanism provided solely at the processing region, and heating temperature of the heating mechanism is controlled by the temperature control unit.

11. An optical processing method, comprising:
a preparatory step of irradiating processing gas passing through a preparatory region with light emitted from a light source; and
a processing step of irradiating an object to be processed arranged in an atmosphere of the processing gas with the light emitted from the light source unit in a processing region continuous from the preparatory region.

12. The optical processing method according to claim 11, wherein
the processing step irradiates the object to be processed arranged in the atmosphere of the processing gas with the light emitted from the light source unit in the processing region continuous from the preparatory region, the processing region having a smaller flow channel cross sectional area than that of the preparatory region, and the processing gas having a faster flow rate in the processing region than in the preparatory region.

13. The optical processing method according to claim 11 or claim 12, wherein
the preparatory step irradiates the processing gas passing through the preparatory region with ultra violet light emitted from the light source unit; and
the processing step irradiates the object to be processed arranged and heated in an atmosphere of the processing gas in the processing region, and
heating temperature at least in the processing step is controlled and temperature of the preparatory region in the preparatory step is made to be lower than the heating temperature.
